(19) United States
(12) Patent Application Publication
(10) Pub. No.: US 2025/0380219 A1
(43) Pub. Date: Dec. 11, 2025

(54) TECHNIQUES FOR BINARY WAKE-UP SIGNAL SEQUENCES

(71) Applicant: QUALCOMM Incorporated, San Diego, CA (US)

(72) Inventors: Wei YANG, San Diego, CA (US); Yuchul KIM, San Diego, CA (US); Ahmed ELSHAFIE, San Diego, CA (US); Zhikun WU, Beijing (CN); Chao WEI, Beijing (CN); Le LIU, San Jose, CA (US); Krishna Kiran MUKKAVILLI, San Diego, CA (US)

(21) Appl. No.: 18/877,223

(22) PCT Filed: Aug. 12, 2022
(86) PCT No.: PCT/CN2022/112046

§ 371 Date: Dec. 19, 2024

(51) Int. Cl. H04W 52/02; H03M 13/15; H04L 27/02; H04W 72/20

(52) U.S. Cl. CPC H04W 52/0235; H03M 13/1515; H04L 27/02; H04W 72/20

(57) ABSTRACT

Methods, systems, and devices for wireless communications are described. A user equipment (UE) may receive control signaling indicating a first binary sequence corresponding to the UE, the first binary sequence included within a set of binary sequences, wherein a sequence distance metrics between each respective pair of binary sequences of the set plurality of binary sequences satisfies a first distance threshold. The UE may receive a radio frequency (RF) waveform within a wake-up signal (WUS) monitoring occasion, and may determine whether the received RF waveform is associated with the first binary sequence. The UE and may then transition from a first operational state to a second operational state associated with a higher power consumption based on determining that the received RF waveform is associated with the first binary sequence.

### CROSS REFERENCE

The present Application is a 371 national stage filing of International PCT Application No. PCT/CN2022/112046 by YANG et al. entitled “TECHNIQUES FOR BINARY WAKE-UP SIGNAL SEQUENCES,” filed Aug. 12, 2022, which is assigned to the assignee hereof, and which is expressly incorporated by reference in its entirety herein.

### TECHNICAL FIELD

The following relates to wireless communications, including techniques for binary wake-up signal (WUS) sequences.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

In some wireless communication systems, a user equipment (UE) may enter a lower power mode of operation (e.g., connected discontinuous reception cycle (CDRX)) in order to conserve power. During a lower power mode, the UE may monitor a set of monitoring occasions for wake-up signals (WUSs) that are used by the network to indicate when there is message traffic waiting to be delivered to the UE.

### SUMMARY

The described techniques relate to improved methods, systems, devices, and apparatuses that support techniques for binary wake-up signal (WUS) sequences. Generally, aspects of the present disclosure are directed to binary WUS sequences that may reduce complexity and processing requirements at receiver devices. In particular, aspects of the present disclosure are directed to a set of binary sequences that are designed to exhibit minimum “sequence distance metrics” from one another to enable receiver devices to compare distances between binary sequences of received WUSs and binary sequences assigned to the respective receiver device. For example, a network may generate a set of binary sequences (e.g., on-off keying (OOK) sequences, frequency-shift keying (FSK) sequences), where sequence distance metrics (e.g., Hamming distances) between each binary sequence in the set are a minimum distance from each other. In this example, the network may assign each UE of a set of UEs (e.g., receiver devices) a respective binary sequence from the set of binary sequences. Upon identifying message traffic waiting to be delivered to a UE, the network may reference a table or other data object to find a binary sequence and corresponding RF waveform for the binary sequence, and may transmit the RF waveform to the UE. The UE then generates a binary sequence based on the received RF waveform, and determines a sequence distance metric between the generated binary sequence and the binary sequence assigned to the UE. If the identified sequence distance metric satisfies a threshold (e.g., if the generated binary sequence is close/similar to the assigned binary sequence), the UE “wakes up” or otherwise enters a higher power operational state in order to receive the message traffic.

A method for wireless communication at a UE is described. The method may include receiving, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold, receiving, while in a first operational state and based on the control signaling, a radio frequency (RF) waveform within a WUS monitoring occasion of the set of multiple WUS monitoring occasions, determining whether the received RF waveform is associated with the first binary sequence, and transitioning from the first operational state to a second operational state based on determining that the received RF waveform is associated with the first binary sequence, where the second operational state is associated with a higher power consumption compared to the first operational state.

An apparatus for wireless communication at a UE is described. The apparatus may include at least one processor, and memory coupled to the at least one processor, the memory storing instructions executable by the at least one processor to cause the UE to receive, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold, receive, while in a first operational state and based on the control signaling, an RF waveform within a WUS monitoring occasion of the set of multiple WUS monitoring occasions, determine whether the received RF waveform is associated with the first binary sequence, and transition from the first operational state to a second operational state based on determining that the received RF waveform is associated with the first binary sequence, where the second operational state is associated with a higher power consumption compared to the first operational state.

Another apparatus for wireless communication at a UE is described. The apparatus may include means for receiving, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold, means for receiving, while in a first operational state and based on the control signaling, an RF waveform within a WUS monitoring occasion of the set of multiple WUS monitoring occasions, means for determining whether the received RF waveform is associated with the first binary sequence, and means for transitioning from the first operational state to a second operational state based on determining that the received RF waveform is associated with the first binary sequence, where the second operational state is associated with a higher power consumption compared to the first operational state.

A non-transitory computer-readable medium storing code for wireless communication at a UE is described. The code may include instructions executable by at least one processor to receive, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold, receive, while in a first operational state and based on the control signaling, an RF waveform within a WUS monitoring occasion of the set of multiple WUS monitoring occasions, determine whether the received RF waveform is associated with the first binary sequence, and transition from the first operational state to a second operational state based on determining that the received RF waveform is associated with the first binary sequence, where the second operational state is associated with a higher power consumption compared to the first operational state.

Some examples of the method, apparatuses, and non-transitory computer-readable medium described herein may further include operations, features, means, or instructions for generating a second binary sequence associated with the received RF waveform and determining a sequence distance metric between the first binary sequence and the second binary sequence, where determining that the received RF waveform may be associated with the first binary sequence may be based on the sequence distance metric satisfying a second distance threshold that may be less than the first distance threshold.

In some examples of the method, apparatuses, and non-transitory computer-readable medium described herein, the sequence distance metric satisfies the second distance threshold based on the sequence distance metric being less than or equal to the second distance threshold.

Some examples of the method, apparatuses, and non-transitory computer-readable medium described herein may further include operations, features, means, or instructions for receiving an indication of the second distance threshold via the control signaling and comparing the sequence distance metric to the second distance threshold based on the control signaling, where transitioning from the first operational state to the second operational state may be based on the comparison.

Some examples of the method, apparatuses, and non-transitory computer-readable medium described herein may further include operations, features, means, or instructions for receiving, while in the first operational state and based on the control signaling, an additional RF waveform within an additional WUS monitoring occasion of the set of multiple WUS monitoring occasions, generating a second binary sequence associated with the additional RF waveform, and remaining in the first operational state based on a sequence distance metric between the first binary sequence and the second binary sequence failing to satisfy a second distance threshold that may be less than the first distance threshold.

In some examples of the method, apparatuses, and non-transitory computer-readable medium described herein, the first distance threshold may be based on a length of the set of multiple binary sequences.

In some examples of the method, apparatuses, and non-transitory computer-readable medium described herein, the first distance threshold may be greater than or equal to half of the length of the set of multiple binary sequences.

In some examples of the method, apparatuses, and non-transitory computer-readable medium described herein, the set of multiple sequence distance metrics between each respective pair of binary sequences satisfy the first distance threshold based on the set of multiple sequence distance metrics being greater than or equal to the first distance threshold.

In some examples of the method, apparatuses, and non-transitory computer-readable medium described herein, the set of multiple binary sequences may be generated based on a matrix generator of a binary linear block code.

In some examples of the method, apparatuses, and non-transitory computer-readable medium described herein, the binary linear block code includes a Golay code, a Reed Muller code, a Reed Solomon code, a Bose-Chaudhuri-Hocquenghem code, a Hamming code, a polar code, a low-density parity-check (LDPC) code, or any combination thereof.

Some examples of the method, apparatuses, and non-transitory computer-readable medium described herein may further include operations, features, means, or instructions for receiving, via the control signaling, additional control signaling, or both, a second binary sequence corresponding to a set of multiple UEs including the UE and determining whether the received RF waveform may be associated with the second binary sequence, where transitioning from the first operational state to the second operational state may be based on the RF waveform being associated with the first binary sequence, the second binary sequence, or both.

Some examples of the method, apparatuses, and non-transitory computer-readable medium described herein may further include operations, features, means, or instructions for receiving, via the control signaling, a scrambling sequence associated with the first binary sequence, where determining whether the received RF waveform may be associated with the first binary sequence may be based on the scrambling sequence.

Some examples of the method, apparatuses, and non-transitory computer-readable medium described herein may further include operations, features, means, or instructions for generating a modified version of the received RF waveform based on the scrambling sequence and determining whether the modified version of the received RF waveform may be associated with the first binary sequence, where transitioning from the first operational state to the second operational state may be based on the modified version of the received RF waveform being associated with the first binary sequence.

In some examples of the method, apparatuses, and non-transitory computer-readable medium described herein, the RF waveform includes an OOK waveform, an FSK waveform, or both.

In some examples of the method, apparatuses, and non-transitory computer-readable medium described herein, the set of multiple sequence distance metrics between each pair of binary sequences include Hamming distance property metrics.

A method for wireless communication at a network entity is described. The method may include transmitting, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold, transmitting, to the UE within a WUS monitoring occasion of the set of multiple WUS monitoring occasions and while the UE is in a first operational state, an RF waveform corresponding to the first binary sequence, where the RF waveform is transmitted based on the control signaling, and communicating message traffic to the UE based on transmitting the RF waveform.

An apparatus for wireless communication at a network entity is described. The apparatus may include at least one processor, and memory coupled to the at least one processor, the memory storing instructions executable by the at least one processor to cause the network entity to transmit, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold, transmit, to the UE within a WUS monitoring occasion of the set of multiple WUS monitoring occasions and while the UE is in a first operational state, an RF waveform corresponding to the first binary sequence, where the RF waveform is transmitted based on the control signaling, and communicate message traffic to the UE based on transmitting the RF waveform.

Another apparatus for wireless communication at a network entity is described. The apparatus may include means for transmitting, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold, means for transmitting, to the UE within a WUS monitoring occasion of the set of multiple WUS monitoring occasions and while the UE is in a first operational state, an RF waveform corresponding to the first binary sequence, where the RF waveform is transmitted based on the control signaling, and means for communicating message traffic to the UE based on transmitting the RF waveform.

A non-transitory computer-readable medium storing code for wireless communication at a network entity is described. The code may include instructions executable by at least one processor to transmit, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold, transmit, to the UE within a WUS monitoring occasion of the set of multiple WUS monitoring occasions and while the UE is in a first operational state, an RF waveform corresponding to the first binary sequence, where the RF waveform is transmitted based on the control signaling, and communicate message traffic to the UE based on transmitting the RF waveform.

Some examples of the method, apparatuses, and non-transitory computer-readable medium described herein may further include operations, features, means, or instructions for identifying the message traffic that may be to be transmitted to the UE, referencing a data object that maps the set of multiple binary sequences to a set of multiple RF waveforms and corresponding UEs based on identifying the message traffic, the set of multiple RF waveforms including the RF waveform, and identifying the RF waveform corresponding to the UE and the first binary sequence based on referencing the data object.

In some examples of the method, apparatuses, and non-transitory computer-readable medium described herein, the first distance threshold may be based on a length of the set of multiple binary sequences.

In some examples of the method, apparatuses, and non-transitory computer-readable medium described herein, the first distance threshold may be greater than or equal to half of the length of the set of multiple binary sequences.

In some examples of the method, apparatuses, and non-transitory computer-readable medium described herein, the set of multiple sequence distance metrics between each respective pair of binary sequences satisfy a distance threshold based on the set of multiple sequence distance metrics being greater than or equal to the distance threshold.

In some examples of the method, apparatuses, and non-transitory computer-readable medium described herein, the set of multiple binary sequences may be generated based on a matrix generator of a binary linear block code.

In some examples of the method, apparatuses, and non-transitory computer-readable medium described herein, the binary linear block code includes a Golay code, a Reed Muller code, a Reed Solomon code, a Bose-Chaudhuri-Hocquenghem code, a Hamming code, a polar code, an LDPC code, or any combination thereof.

Some examples of the method, apparatuses, and non-transitory computer-readable medium described herein may further include operations, features, means, or instructions for transmitting, via the control signaling, additional control signaling, or both, a third binary sequence corresponding to a set of multiple UEs including the UE, transmitting, to the set of multiple UEs within an additional WUS monitoring occasion of the set of multiple WUS monitoring occasions, an additional RF waveform corresponding to the third binary sequence, and communicating additional message traffic to the set of multiple UEs based on transmitting the additional RF waveform.

Some examples of the method, apparatuses, and non-transitory computer-readable medium described herein may further include operations, features, means, or instructions for transmitting, via the control signaling, a scrambling sequence associated with the first binary sequence, where transmitting the RF waveform may be based on the scrambling sequence.

Some examples of the method, apparatuses, and non-transitory computer-readable medium described herein may further include operations, features, means, or instructions for generating the RF waveform based on the scrambling sequence.

Some examples of the method, apparatuses, and non-transitory computer-readable medium described herein may further include operations, features, means, or instructions for transmitting an indication of a distance threshold associated with the set of multiple binary sequences via the control signaling, where transmitting the RF waveform, communicating the message traffic, or both, may be based on the indication of the distance threshold.

In some examples of the method, apparatuses, and non-transitory computer-readable medium described herein, the RF waveform includes an OOK waveform, an FSK waveform, or both.

In some examples of the method, apparatuses, and non-transitory computer-readable medium described herein, the set of multiple sequence distance metrics between each pair of binary sequences include Hamming distance property metrics.

### BRIEF DESCRIPTION OF THE DRAWINGS

FIG. 1 illustrates an example of a wireless communications system that supports techniques for binary wake-up signal (WUS) sequences in accordance with one or more aspects of the present disclosure.

FIG. 2 illustrates an example of a wireless communications system that supports techniques for binary WUS sequences in accordance with one or more aspects of the present disclosure.

FIG. 3 illustrates an example of a process flow that supports techniques for binary WUS sequences in accordance with one or more aspects of the present disclosure.

FIGS. 4 and 5 show block diagrams of devices that support techniques for binary WUS sequences in accordance with one or more aspects of the present disclosure.

FIG. 6 shows a block diagram of a communications manager that supports techniques for binary WUS sequences in accordance with one or more aspects of the present disclosure.

FIG. 7 shows a diagram of a system including a device that supports techniques for binary WUS sequences in accordance with one or more aspects of the present disclosure.

FIGS. 8 and 9 show block diagrams of devices that support techniques for binary WUS sequences in accordance with one or more aspects of the present disclosure.

FIG. 10 shows a block diagram of a communications manager that supports techniques for binary WUS sequences in accordance with one or more aspects of the present disclosure.

FIG. 11 shows a diagram of a system including a device that supports techniques for binary WUS sequences in accordance with one or more aspects of the present disclosure.

FIGS. 12 through 14 show flowcharts illustrating methods that support techniques for binary WUS sequences in accordance with one or more aspects of the present disclosure.

### DETAILED DESCRIPTION

In some wireless communication systems, a user equipment (UE) may enter a lower power mode of operation (e.g., connected discontinuous reception cycle (CDRX)) in order to conserve power. During a lower power mode, the UE may use a designated “wake-up receiver” to monitor a set of monitoring occasions for wake-up signals (WUSs) that are used by the network to indicate when there is message traffic waiting to be delivered to the UE. Utilizing a separate wake-up receiver may enable the UE to keep higher-power consuming components (e.g., main radio, baseband component) powered off until such components are needed to receive message traffic or perform other communications. As such, low-complexity WUSs are required to enable wake-up receivers to process WUSs without complicated baseband processing.

When considering the design for WUSs, there are conflicting desires to reduce “false alarms” (e.g., when a receiver determines that a WUS is intended for the receiver, when the WUS was actually intended for another receiver), while also reducing mis-detections (e.g., when a WUS is intended for a receiver, but the receiver did not identify the WUS as an indication to wake up). However, in order to keep false-alarm and mis-detection rates within allowable ranges using conventional WUS techniques, receivers (e.g., UEs) may be expected to compare received WUS sequences to each candidate WUS sequence in the universe of possible WUS sequences in order to verify whether or not received WUS sequences are intended for the receiver, thereby reducing potential power saving capabilities at the receiver.

Accordingly, aspects of the present disclosure are directed to the use of binary WUS sequences that may reduce complexity and processing requirements at receiver devices. In particular, aspects of the present disclosure are directed to a set of binary sequences that are designed to exhibit minimum “sequence distance metrics” from one another to enable receiver devices to compare distances between binary sequences of received WUSs and binary sequences assigned to the respective receiver device.

For example, a network may generate a set of binary sequences, where sequence distance metrics (e.g., Hamming distances) between each binary sequence in the set is at least a defined distance (e.g., at least a minimum distance) from each other. In this example, the network may assign UEs (e.g., receiver devices) a respective binary sequence from the set of binary sequences. Upon identifying message traffic waiting to be delivered to a UE, the network may reference a table or other data object to find a binary sequence and generate a corresponding RF waveform (e.g., on-off keying (OOK) waveform, frequency-shift keying (FSK) waveform) for the binary sequence, and may transmit the RF waveform to the UE. The UE is configured to determine whether the received RF sequence is associated with (e.g., matches) the binary sequence assigned to the UE. If the UE determines that the received RF waveform is associated with the assigned binary sequence, the UE “wakes up” or otherwise enters a higher power operational state in order to receive the message traffic.

Aspects of the disclosure are initially described in the context of wireless communications systems. Additional aspects of the disclosure are described in the context of an example process flow. Aspects of the disclosure are further illustrated by and described with reference to apparatus diagrams, system diagrams, and flowcharts that relate to techniques for binary WUS sequences.

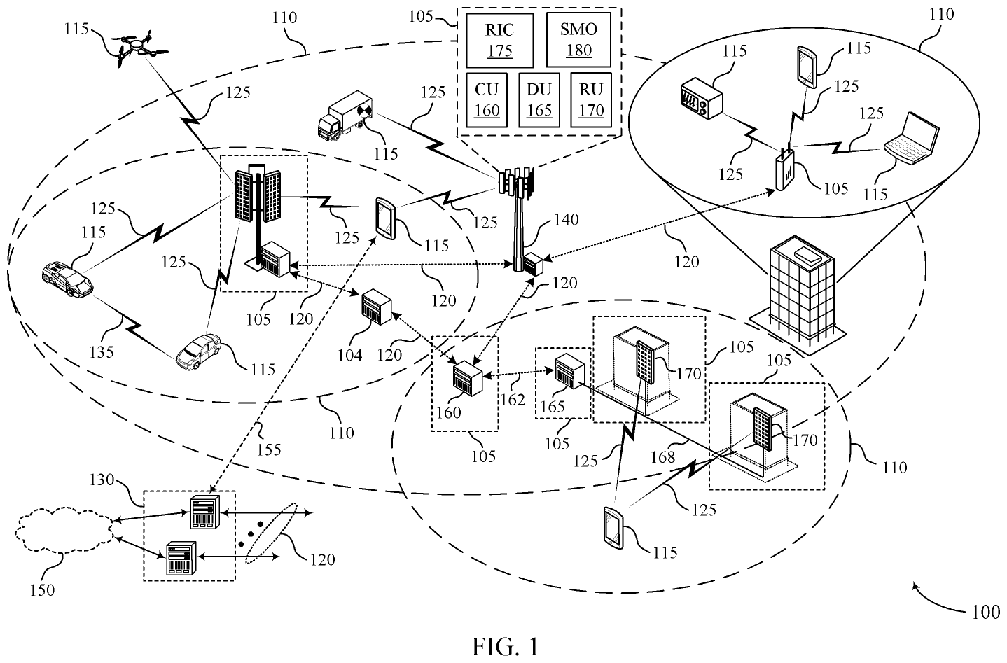

FIG. 1 illustrates an example of a wireless communications system 100 that supports techniques for binary WUS sequences in accordance with one or more aspects of the present disclosure. The wireless communications system 100 may include one or more network entities 105, one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via one or more communication links 125 (e.g., a radio frequency (RF) access link). For example, a network entity 105 may support a coverage area 110 (e.g., a geographic coverage area) over which the UEs 115 and the network entity 105 may establish one or more communication links 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with the core network 130, or with one another, or both. For example, network entities 105 may communicate with the core network 130 via one or more backhaul communication links 120 (e.g., in accordance with an S1, N2, N3, or other interface protocol). In some examples, network entities 105 may communicate with one another via a backhaul communication link 120 (e.g., in accordance with an X2, Xn, or other interface protocol) either directly (e.g., directly between network entities 105) or indirectly (e.g., via a core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication links 120, midhaul communication links 162, or fronthaul communication links 168 may be or include one or more wired links (e.g., an electrical link, an optical fiber link), one or more wireless links (e.g., a radio link, a wireless optical link), among other examples or various combinations thereof. A UE 115 may communicate with the core network 130 via a communication link 155.

One or more of the network entities 105 described herein may include or may be referred to as a base station 140 (e.g., a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within a single network entity 105 (e.g., a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU) 160, a distributed unit (DU) 165, a radio unit (RU) 170, a RAN Intelligent Controller (RIC) 175 (e.g., a Near-Real Time RIC (Near-RT RIC), a Non-Real Time RIC (Non-RT RIC)), a Service Management and Orchestration (SMO) 180 system, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaption protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or more RUs 170). In some cases, a functional split between a CU 160 and a DU 165, or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (e.g., F1, F1-c, F1-u), and a DU 165 may be connected to one or more RUs 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities 105 that are in communication via such communication links.

In wireless communications systems (e.g., wireless communications system 100), infrastructure and spectral resources for radio access may support wireless backhaul link capabilities to supplement wired backhaul connections, providing an IAB network architecture (e.g., to a core network 130). In some cases, in an IAB network, one or more network entities 105 (e.g., IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (e.g., a donor base station 140). The one or more donor network entities 105 (e.g., IAB donors) may be in communication with one or more additional network entities 105 (e.g., IAB nodes 104) via supported access and backhaul links (e.g., backhaul communication links 120). IAB nodes 104 may include an IAB mobile termination (IAB-MT) controlled (e.g., scheduled) by DUs 165 of a coupled IAB donor. An IAB-MT may include an independent set of antennas for relay of communications with UEs 115, or may share the same antennas (e.g., of an RU 170) of an IAB node 104 used for access via the DU 165 of the IAB node 104 (e.g., referred to as virtual IAB-MT (vIAB-MT)). In some examples, the IAB nodes 104 may include DUs 165 that support communication links with additional entities (e.g., IAB nodes 104, UEs 115) within the relay chain or configuration of the access network (e.g., downstream). In such cases, one or more components of the disaggregated RAN architecture (e.g., one or more IAB nodes 104 or components of IAB nodes 104) may be configured to operate according to the techniques described herein.

For instance, an access network (AN) or RAN may include communications between access nodes (e.g., an IAB donor), IAB nodes 104, and one or more UEs 115. The IAB donor may facilitate connection between the core network 130 and the AN (e.g., via a wired or wireless connection to the core network 130). That is, an IAB donor may refer to a RAN node with a wired or wireless connection to core network 130. The IAB donor may include a CU 160 and at least one DU 165 (e.g., and RU 170), in which case the CU 160 may communicate with the core network 130 via an interface (e.g., a backhaul link). IAB donor and IAB nodes 104 may communicate via an F1 interface according to a protocol that defines signaling messages (e.g., an F1 AP protocol). Additionally, or alternatively, the CU 160 may communicate with the core network via an interface, which may be an example of a portion of backhaul link, and may communicate with other CUs 160 (e.g., a CU 160 associated with an alternative IAB donor) via an Xn-C interface, which may be an example of a portion of a backhaul link.

An IAB node 104 may refer to a RAN node that provides IAB functionality (e.g., access for UEs 115, wireless self-backhauling capabilities). A DU 165 may act as a distributed scheduling node towards child nodes associated with the IAB node 104, and the IAB-MT may act as a scheduled node towards parent nodes associated with the IAB node 104. That is, an IAB donor may be referred to as a parent node in communication with one or more child nodes (e.g., an IAB donor may relay transmissions for UEs through one or more other IAB nodes 104). Additionally, or alternatively, an IAB node 104 may also be referred to as a parent node or a child node to other IAB nodes 104, depending on the relay chain or configuration of the AN. Therefore, the IAB-MT entity of IAB nodes 104 may provide a Uu interface for a child IAB node 104 to receive signaling from a parent IAB node 104, and the DU interface (e.g., DUs 165) may provide a Uu interface for a parent IAB node 104 to signal to a child IAB node 104 or UE 115.

For example, IAB node 104 may be referred to as a parent node that supports communications for a child IAB node, or referred to as a child IAB node associated with an IAB donor, or both. The IAB donor may include a CU 160 with a wired or wireless connection (e.g., a backhaul communication link 120) to the core network 130 and may act as parent node to IAB nodes 104. For example, the DU 165 of IAB donor may relay transmissions to UEs 115 through IAB nodes 104, or may directly signal transmissions to a UE 115, or both. The CU 160 of IAB donor may signal communication link establishment via an F1 interface to IAB nodes 104, and the IAB nodes 104 may schedule transmissions (e.g., transmissions to the UEs 115 relayed from the IAB donor) through the DUs 165. That is, data may be relayed to and from IAB nodes 104 via signaling via an NR Uu interface to MT of the IAB node 104. Communications with IAB node 104 may be scheduled by a DU 165 of IAB donor and communications with IAB node 104 may be scheduled by DU 165 of IAB node 104.

In the case of the techniques described herein applied in the context of a disaggregated RAN architecture, one or more components of the disaggregated RAN architecture may be configured to support techniques for binary WUS sequences as described herein. For example, some operations described as being performed by a UE 115 or a network entity 105 (e.g., a base station 140) may additionally, or alternatively, be performed by one or more components of the disaggregated RAN architecture (e.g., IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a multimedia/entertainment device (e.g., a radio, a MP3 player, or a video device), a camera, a gaming device, a navigation/positioning device (e.g., GNSS (global navigation satellite system) devices based on, for example, GPS (global positioning system), Beidou, GLONASS, or Galileo, or a terrestrial-based device), a tablet computer, a laptop computer, a personal computer, a netbook, a smartbook, a personal computer, a smart device, a wearable device (e.g., a smart watch, smart clothing, smart glasses, virtual reality goggles, a smart wristband, smart jewelry (e.g., a smart ring, a smart bracelet)), a drone, a robot/robotic device, a vehicle, a vehicular device, a meter (e.g., parking meter, electric meter, gas meter, water meter), a monitor, a gas pump, an appliance (e.g., kitchen appliance, washing machine, dryer), a location tag, a medical/healthcare device, an implant, a sensor/actuator, a display, or any other suitable device configured to communicate via a wireless or wired medium. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (e.g., an access link) using resources associated with one or more carriers. The term “carrier” may refer to a set of RF spectrum resources having a defined physical layer structure for supporting the communication links 125. For example, a carrier used for a communication link 125 may include a portion of an RF spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities 105).

In some examples, such as in a carrier aggregation configuration, a carrier may also have acquisition signaling or control signaling that coordinates operations for other carriers. A carrier may be associated with a frequency channel (e.g., an evolved universal mobile telecommunication system terrestrial radio access (E-UTRA) absolute RF channel number (EARFCN)) and may be identified according to a channel raster for discovery by the UEs 115. A carrier may be operated in a standalone mode, in which case initial acquisition and connection may be conducted by the UEs 115 via the carrier, or the carrier may be operated in a non-standalone mode, in which case a connection is anchored using a different carrier (e.g., of the same or a different radio access technology).

The communication links 125 shown in the wireless communications system 100 may include downlink transmissions (e.g., forward link transmissions) from a network entity 105 to a UE 115, uplink transmissions (e.g., return link transmissions) from a UE 115 to a network entity 105, or both, among other configurations of transmissions. Carriers may carry downlink or uplink communications (e.g., in an FDD mode) or may be configured to carry downlink and uplink communications (e.g., in a TDD mode).

A carrier may be associated with a particular bandwidth of the RF spectrum and, in some examples, the carrier bandwidth may be referred to as a “system bandwidth” of the carrier or the wireless communications system 100. For example, the carrier bandwidth may be one of a set of bandwidths for carriers of a particular radio access technology (e.g., 1.4, 3, 5, 10, 15, 20, 40, or 80 megahertz (MHz)). Devices of the wireless communications system 100 (e.g., the network entities 105, the UEs 115, or both) may have hardware configurations that support communications using a particular carrier bandwidth or may be configurable to support communications using one of a set of carrier bandwidths. In some examples, the wireless communications system 100 may include network entities 105 or UEs 115 that support concurrent communications using carriers associated with multiple carrier bandwidths. In some examples, each served UE 115 may be configured for operating using portions (e.g., a sub-band, a BWP) or all of a carrier bandwidth.

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

One or more numerologies for a carrier may be supported, and a numerology may include a subcarrier spacing (Δf) and a cyclic prefix. A carrier may be divided into one or more BWPs having the same or different numerologies. In some examples, a UE 115 may be configured with multiple BWPs. In some examples, a single BWP for a carrier may be active at a given time and communications for the UE 115 may be restricted to one or more active BWPs.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and Ne may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

In some examples, a network entity 105 (e.g., a base station 140, an RU 170) may be movable and therefore provide communication coverage for a moving coverage area 110. In some examples, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

The wireless communications system 100 may support synchronous or asynchronous operation. For synchronous operation, network entities 105 (e.g., base stations 140) may have similar frame timings, and transmissions from different network entities 105 may be approximately aligned in time. For asynchronous operation, network entities 105 may have different frame timings, and transmissions from different network entities 105 may, in some examples, not be aligned in time. The techniques described herein may be used for either synchronous or asynchronous operations.

Some UEs 115, such as MTC or IoT devices, may be low cost or low complexity devices and may provide for automated communication between machines (e.g., via Machine-to-Machine (M2M) communication). M2M communication or MTC may refer to data communication technologies that allow devices to communicate with one another or a network entity 105 (e.g., a base station 140) without human intervention. In some examples, M2M communication or MTC may include communications from devices that integrate sensors or meters to measure or capture information and relay such information to a central server or application program that uses the information or presents the information to humans interacting with the application program. Some UEs 115 may be designed to collect information or enable automated behavior of machines or other devices. Examples of applications for MTC devices include smart metering, inventory monitoring, water level monitoring, equipment monitoring, healthcare monitoring, wildlife monitoring, weather and geological event monitoring, fleet management and tracking, remote security sensing, physical access control, and transaction-based business charging. In an aspect, techniques disclosed herein may be applicable to MTC or IoT UEs. MTC or IoT UEs may include MTC/enhanced MTC (eMTC, also referred to as CAT-M, Cat M1) UEs, NB-IoT (also referred to as CAT NB1) UEs, as well as other types of UEs. eMTC and NB-IoT may refer to future technologies that may evolve from or may be based on these technologies. For example, eMTC may include FeMTC (further eMTC), eFeMTC (enhanced further eMTC), and mMTC (massive MTC), and NB-IoT may include eNB-IoT (enhanced NB-IoT), and FeNB-IoT (further enhanced NB-IoT).

Some UEs 115 may be configured to employ operating modes that reduce power consumption, such as half-duplex communications (e.g., a mode that supports one-way communication via transmission or reception, but not transmission and reception concurrently). In some examples, half-duplex communications may be performed at a reduced peak rate. Other power conservation techniques for the UEs 115 include entering a power saving deep sleep mode when not engaging in active communications, operating using a limited bandwidth (e.g., according to narrowband communications), or a combination of these techniques. For example, some UEs 115 may be configured for operation using a narrowband protocol type that is associated with a defined portion or range (e.g., set of subcarriers or resource blocks (RBs)) within a carrier, within a guard-band of a carrier, or outside of a carrier.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs 115 via a device-to-device (D2D) communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to each of the other UEs 115 in the group. In some examples, a network entity 105 may facilitate the scheduling of resources for D2D communications. In some other examples, D2D communications may be carried out between the UEs 115 without an involvement of a network entity 105.

In some systems, a D2D communication link 135 may be an example of a communication channel, such as a sidelink communication channel, between vehicles (e.g., UEs 115). In some examples, vehicles may communicate using vehicle-to-everything (V2X) communications, vehicle-to-vehicle (V2V) communications, or some combination of these. A vehicle may signal information related to traffic conditions, signal scheduling, weather, safety, emergencies, or any other information relevant to a V2X system. In some examples, vehicles in a V2X system may communicate with roadside infrastructure, such as roadside units, or with the network via one or more network nodes (e.g., network entities 105, base stations 140, RUs 170) using vehicle-to-network (V2N) communications, or with both.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than 100 kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

The network entities 105 or the UEs 115 may use MIMO communications to exploit multipath signal propagation and increase spectral efficiency by transmitting or receiving multiple signals via different spatial layers. Such techniques may be referred to as spatial multiplexing. The multiple signals may, for example, be transmitted by the transmitting device via different antennas or different combinations of antennas. Likewise, the multiple signals may be received by the receiving device via different antennas or different combinations of antennas. Each of the multiple signals may be referred to as a separate spatial stream and may carry information associated with the same data stream (e.g., the same codeword) or different data streams (e.g., different codewords). Different spatial layers may be associated with different antenna ports used for channel measurement and reporting. MIMO techniques include single-user MIMO (SU-MIMO), for which multiple spatial layers are transmitted to the same receiving device, and multiple-user MIMO (MU-MIMO), for which multiple spatial layers are transmitted to multiple devices.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

A network entity 105 or a UE 115 may use beam sweeping techniques as part of beamforming operations. For example, a network entity 105 (e.g., a base station 140, an RU 170) may use multiple antennas or antenna arrays (e.g., antenna panels) to conduct beamforming operations for directional communications with a UE 115. Some signals (e.g., synchronization signals, reference signals, beam selection signals, or other control signals) may be transmitted by a network entity 105 multiple times along different directions. For example, the network entity 105 may transmit a signal according to different beamforming weight sets associated with different directions of transmission. Transmissions along different beam directions may be used to identify (e.g., by a transmitting device, such as a network entity 105, or by a receiving device, such as a UE 115) a beam direction for later transmission or reception by the network entity 105.

Some signals, such as data signals associated with a particular receiving device, may be transmitted by transmitting device (e.g., a transmitting network entity 105, a transmitting UE 115) along a single beam direction (e.g., a direction associated with the receiving device, such as a receiving network entity 105 or a receiving UE 115). In some examples, the beam direction associated with transmissions along a single beam direction may be determined based on a signal that was transmitted along one or more beam directions. For example, a UE 115 may receive one or more of the signals transmitted by the network entity 105 along different directions and may report to the network entity 105 an indication of the signal that the UE 115 received with a highest signal quality or an otherwise acceptable signal quality.

In some examples, transmissions by a device (e.g., by a network entity 105 or a UE 115) may be performed using multiple beam directions, and the device may use a combination of digital precoding or beamforming to generate a combined beam for transmission (e.g., from a network entity 105 to a UE 115). The UE 115 may report feedback that indicates precoding weights for one or more beam directions, and the feedback may correspond to a configured set of beams across a system bandwidth or one or more sub-bands. The network entity 105 may transmit a reference signal (e.g., a cell-specific reference signal (CRS), a channel state information reference signal (CSI-RS)), which may be precoded or unprecoded. The UE 115 may provide feedback for beam selection, which may be a precoding matrix indicator (PMI) or codebook-based feedback (e.g., a multi-panel type codebook, a linear combination type codebook, a port selection type codebook). Although these techniques are described with reference to signals transmitted along one or more directions by a network entity 105 (e.g., a base station 140, an RU 170), a UE 115 may employ similar techniques for transmitting signals multiple times along different directions (e.g., for identifying a beam direction for subsequent transmission or reception by the UE 115) or for transmitting a signal along a single direction (e.g., for transmitting data to a receiving device).

A receiving device (e.g., a UE 115) may perform reception operations in accordance with multiple receive configurations (e.g., directional listening) when receiving various signals from a receiving device (e.g., a network entity 105), such as synchronization signals, reference signals, beam selection signals, or other control signals. For example, a receiving device may perform reception in accordance with multiple receive directions by receiving via different antenna subarrays, by processing received signals according to different antenna subarrays, by receiving according to different receive beamforming weight sets (e.g., different directional listening weight sets) applied to signals received at multiple antenna elements of an antenna array, or by processing received signals according to different receive beamforming weight sets applied to signals received at multiple antenna elements of an antenna array, any of which may be referred to as “listening” according to different receive configurations or receive directions. In some examples, a receiving device may use a single receive configuration to receive along a single beam direction (e.g., when receiving a data signal). The single receive configuration may be aligned along a beam direction determined based on listening according to different receive configuration directions (e.g., a beam direction determined to have a highest signal strength, highest signal-to-noise ratio (SNR), or otherwise acceptable signal quality based on listening according to multiple beam directions).

The wireless communications system 100 may be a packet-based network that operates according to a layered protocol stack. In the user plane, communications at the bearer or PDCP layer may be IP-based. An RLC layer may perform packet segmentation and reassembly to communicate via logical channels. A MAC layer may perform priority handling and multiplexing of logical channels into transport channels. The MAC layer also may implement error detection techniques, error correction techniques, or both to support retransmissions to improve link efficiency. In the control plane, an RRC layer may provide establishment, configuration, and maintenance of an RRC connection between a UE 115 and a network entity 105 or a core network 130 supporting radio bearers for user plane data. A PHY layer may map transport channels to physical channels.

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., a communication link 125, a D2D communication link 135). HARQ may include a combination of error detection (e.g., using a cyclic redundancy check (CRC)), forward error correction (FEC), and retransmission (e.g., automatic repeat request (ARQ)). HARQ may improve throughput at the MAC layer in poor radio conditions (e.g., low signal-to-noise conditions). In some examples, a device may support same-slot HARQ feedback, in which case the device may provide HARQ feedback in a specific slot for data received via a previous symbol in the slot. In some other examples, the device may provide HARQ feedback in a subsequent slot, or according to some other time interval.

The network entities 105, UEs 115, and other wireless devices of the wireless communications system 100 may be configured to support binary WUS sequence configurations that may reduce complexity and processing requirements at receiver devices. In particular, the wireless communications system 100 may support a set of binary sequences that are designed to exhibit minimum “sequence distance metrics” from one another to enable receiver devices to compare distances between binary sequences of received WUSs and binary sequences assigned to the respective receiver device.

For example, a network entity 105 of the wireless communications system 100 may generate a set of binary sequences, where sequence distance metrics (e.g., Hamming distances) between each binary sequence in the set are a minimum distance from each other. The set of binary sequences may be generated using a binary linear block code, including a Golay code, a Reed Muller code, a Reed Solomon code, a Bose-Chaudhuri-Hocquenghem code, a Hamming code, a polar code, a low-density parity-check (LDPC) code, on-off keying (OOK) sequences, frequency-shift keying (FSK) sequences, or any combination thereof.

In this example, the network may assign UEs 115 (e.g., receiver devices) a respective binary sequence from the set of binary sequences. Upon identifying message traffic waiting to be delivered to a UE 115, the network may reference a table or other data object to find a binary sequence and corresponding RF waveform (e.g., OOK waveform, FSK waveform) for the binary sequence, and may transmit the RF waveform to the UE 115. The UE 115 may be configured to determine whether the received RF sequence is associated with (e.g., matches) the binary sequence assigned to the UE 115. If the UE 115 determines that the received RF waveform is associated with the assigned binary sequence, the UE 115 “wakes up” or otherwise enters a higher power operational state in order to receive the message traffic.

When evaluating whether a received RF waveform is associated with a binary sequence assigned to the UE 115, the UE 115 may be configured to generate an additional binary sequence associated with the received RF waveform, and compare the additional binary sequence to the binary sequence(s) assigned to the UE 115. For instance, UE 115 may be configured to generate a binary sequence based on the received RF waveform, and determine a sequence distance metric between the generated binary sequence and the binary sequence assigned to the UE 115. If the identified sequence distance metric satisfies a threshold (e.g., if the generated binary sequence is close/similar to the assigned binary sequence), the UE 115 “wakes up” or otherwise enters a higher power operational state in order to receive the message traffic.

Techniques described herein may enable the use of binary WUS sequences that reduce processing requirements and complexity at receiver devices. In particular, by generating a set of binary sequences that each exhibit a minimum distance threshold from one another, aspects of the present disclosure may enable receiver devices (e.g., UEs 115) to compare binary sequences associated with received RF waveforms to the one or more binary sequences assigned to the receiver device. In other words, techniques described herein may reduce or eliminate the need for receiver devices to compare binary sequences to every binary sequence within the universe of binary sequences used by the network. As such, techniques described herein may reduce power consumption associated with processing WUSs at receiver devices, and improve power-saving capabilities of receiver devices operating in lower-power states. Moreover, the binary WUS sequence configurations described herein may reduce false alarms and mis-detections for WUSs, further reducing power consumption at receiver devices, improving the efficiency and reliability of WUSs, and leading to a more efficient use of wireless resources.

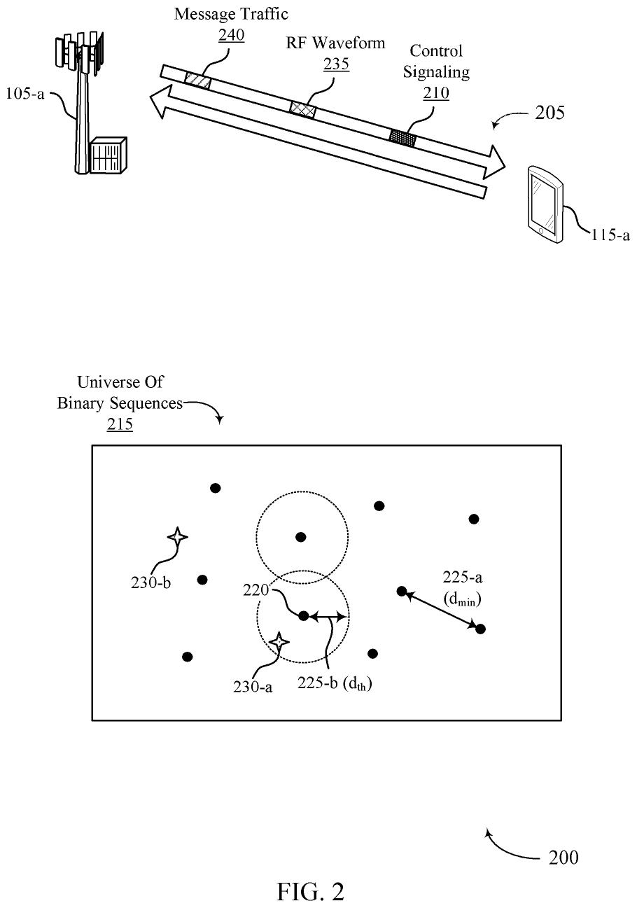

FIG. 2 illustrates an example of a wireless communications system 200 that supports techniques for binary WUS sequences in accordance with one or more aspects of the present disclosure. In some examples, aspects of the wireless communications system 200 may implement, or be implemented by, aspects of the wireless communications system 100. In particular, the wireless communications system 200 may support binary WUS configurations, as described with respect to FIG. 1.

The wireless communications system 200 may include a network entity 105-a and a UE 115-a. The UE 115-a may communicate with the network entity 105-a using a communication link 205, which may be an example of an NR or LTE link between the respective UE 115-a and the network entity 105-a. In some cases, the communication link 205 may include an example of an access link (e.g., Uu links) which may include a bi-directional link that enables both uplink and downlink communication. For example, the UE 115-a may transmit uplink signals, such as uplink control signals or uplink data signals, to one or more components of the network entity 105-a using the communication link 205, and one or more components of the network entity 105-a may transmit downlink signals, such as downlink control signals or downlink data signals, to the UE 115-a using the communication link 205.

As noted previously herein, in some cases, UEs 115 may enter lower power modes of operation (e.g., CDRX) in order to conserve power. During a lower power mode, the UE 115-a may use a designated “wake-up receiver” to monitor a set of monitoring occasions for WUSs that are used by the network to indicate when there is message traffic waiting to be delivered to the UE 115-a. Utilizing a separate wake-up receiver may enable the UE 115-a to keep higher-power consuming components (e.g., main radio, baseband component) powered off until such components are needed to receive message traffic or perform other communications.

As such, low-complexity WUSs are required to enable wake-up receivers to process WUSs without complicated baseband processing. Some potential waveforms that do not require complicated baseband processing may include OOK waveforms and FSK waveforms, which can be demodulated at a receiver with simple filters and envelop detectors. For these WUS modulation schemes, the receiver device (e.g., wake-up receiver, low-power receiver) may generate one bit of information for each of the received symbols. In order to support waking up more than one receiver with a single WUS, and to be able to combat inter-cell interferences, aspects of the present disclosure are directed to the use of the sequences generated based on the detected bits.

In the context of OOK and FSK waveforms (and other low-complexity modulations), the native bit error rate offered by the (uncoded) modulation may be too high when the channel condition between transmitter and the receiver is poor. In other words, OOK and FSK waveforms may be susceptible to low channel quality conditions. As such, there is a need for a channel code or sequence to provide better error protection. In this case, the receiver can detect a sequence of bits based on a received RF waveform (e.g., OOK and FSK waveform), and make a determination of the transmitter's message using the sequence of detected bits (e.g., use the sequence of detected bits to determine whether or not the received WUS is intended for the receiver).

In the application of low-power WUSs (LP-WUSs), the transmitter (e.g., the network entity 105-a, or another UE 115 over sidelink) may want to wake up different receiver devices during different LP-WUS monitoring occasions. For example, the network entity 105-a may wake up the UE 115-a during a first WUS monitoring occasion, and wake up a different UE 115 during a subsequent monitoring occasion. In this case, the transmitter or network may assign different sequences to different receivers/groups of receivers, where the receivers are configured to use the assigned sequences to evaluate WUSs. For example, the network entity 105-a may assign a WUS sequence to the UE 115-a. In this example, the UE 115-a may generate sequences of bits based on WUSs received from the network entity 105-a, and may compare the generated sequences of bits to the sequence which was assigned to the UE 115-a to determine whether or not the respective WUSs are intended to wake up the UE 115-a or not.

When considering the design for WUSs (e.g., LP-WUSs), there are two types of error events: (1) false alarms, and (2) mis-detections. A false alarm may occur when the network entity 105-a (or another transmitter device) transmits an RF waveform/sequence (or does not transmit anything), and the UE 115-a falsely detects that the received RF waveform/sequence is intended for the UE 115-a. In other words, a false alarm occurs when a receiver determines that a WUS is intended for the receiver, when the WUS was actually intended for another receiver (or if there was not actually a WUS).

Comparatively, a mis-detection may occur when the network entity 105-a transmits the intended RF waveform/sequence for the UE 115-a, but the UE 115-a does not correctly detect the RF waveform/sequence. In other words, a mis-detection occurs when a WUS is intended for a receiver, but the receiver does not correctly identify the WUS as an indication to wake up.

When considering the design for WUSs, there are conflicting desires to reduce these false alarms, while also reducing mis-detections. As such, there is a need for a set of binary sequences such that, at a given SNR, the mis-detection rate is minimized under the condition that the false alarm rate is below a target. In other words, there is a need for WUS sequence configurations that reduce mis-detection rates to below some threshold, while simultaneously keeping false alarm rates below some threshold.

However, in order to keep false-alarm and mis-detection rates within allowable ranges using conventional WUS techniques, receivers (e.g., UEs 115) may be expected to compare received WUS sequences to each candidate WUS sequence in a universe of possible WUS sequences in order to verify whether or not received WUS sequences are intended for the receiver, thereby reducing potential power saving capabilities at the receiver.

An example may prove to be illustrative. In this example, there are K WUS groups in the system associated with K sequences denoted by s₁, . . . , sₖ, where the j^{th} sequence sⱼ is a sequence that is assigned to (e.g., intended for) the receiver (or receiver group) j (j=1, . . . , K). In a given WUS monitoring occasion, the network entity 105-a (or other transmitter device) may either transmit nothing, or select one of the K sequences (e.g., select one of s₁, . . . , sₖ). Moreover, the network entity 105-a may not be able to transmit more than one sequence within a single monitoring occasion.

Within each monitoring occasion, receiver devices may be configured to perform composite hypothesis testing to evaluate whether waveforms received within the respective monitoring occasions are intended for the respective receiver devices. For example, the UE 115-a may be assigned sequence s₁, and may determine either a true hypothesis (H₁) or a null hypothesis (H₀) for each monitoring occasion. In this example, the UE 115-a may determine a true hypothesis (H₁) if the UE 115-a determines that a RF waveform received within a WUS monitoring occasion included (or was associated with) the sequence s₁. Comparatively, the UE 115-a may determine a null hypothesis (H₀) if the UE 115-a determines that a RF waveform received within a WUS monitoring occasion included (or was associated with) a different sequence s₁, where j≠1 (denoted as H_{0,j}), or if the UE 115-a does not detect any RF waveforms within the WUS monitoring occasion (denoted as H_{0,0}).

In this example, in order to evaluate RF waveforms within WUS monitoring occasions, the UE 115-a may be expected to find a test f:Y→{0,1} that solves Equations 1-3 below:

$$max Pr [ f ( Y ) = 1 \vert {H}_{1} ] ( success probability ) \qquad ( 1 )$$

$$s . t . Pr [ f ( Y ) = 1 \vert {H}_{0 , 0} ] \leq {p}_{FA} \qquad ( 2 )$$

$$Pr [ f ( Y ) = 1 \vert {H}_{0 , j} ] \leq {p}_{FA} ∀ \neq 1 \qquad ( 3 )$$

where p_{FA} denotes the false alarm target, and Y denotes the received signal (e.g., WUS received within a WUS monitoring occasion).

The mathematical problem illustrated in Equations 1-3 above is known as “composite hypothesis testing” in statistics, and there is no known strategy that achieves the optimal solution in the general case. Stated differently, solving the mathematical problem illustrated in Equations 1-3 above may require complex computational resources and processing power at the receiver devices, which effectively reduce the power-saving capabilities of the receiver devices in the low-power states. In particular, in the LP-WUS setup, a receiver device may not only need to check the “Hamming distance” between each received signal and the sequence(s) assigned to the receiver device, but may also need to check the distance with respect to all other possible sequences in the network (e.g., check distances between the received sequences and all other sequences assigned to all other receiver devices in the network). As such, conventional WUS designs require receiver devices to perform complex and complicated processing to evaluate WUSs.

Accordingly, aspects of the present disclosure are directed to the use of binary WUS sequences that may reduce complexity and processing requirements at receiver devices. Aspects of the present disclosure are directed WUS sequence configurations that enable receiver devices to make decisions regarding WUSs based on the receiver's own assigned sequences, while still meeting false alarm conditions under all null hypotheses. In other words, aspects of the present disclosure are directed to a set of binary sequences that are designed to exhibit minimum “sequence distance metrics” from one another to enable receiver devices to compare distances between binary sequences of received WUSs and binary sequences assigned to the respective receiver device (and without having to compare binary sequences to other sequence assigned to other receivers).

For example, referring to the wireless communications system 200 illustrated in FIG. 2, the UE 115-a may receive, from the network entity 105-a, control signaling 210 indicating a first binary sequence 220 corresponding to the UE 115-a. In other words, the network entity 105-a may “assign” (e.g., associate with, attribute to, etc.) the first binary sequence 220 to the UE 115-a. In some aspects, the first binary sequence 220 may be included within a set or universe of binary sequences 215 used within the network, where sequence distance metrics (e.g., Hamming distance property metrics) between each respective pair of binary sequences of the set/universe of binary sequences 215 satisfies a first distance threshold 225-a. In this example, the circles or dots within the universe of binary sequences 215 each represent a respective codeword or binary sequence that may be assigned to respective receiver devices within the network.

In other words, the wireless communications system 200 may utilize codewords (e.g., binary sequences) from a code with sufficient minimum Hamming distance properties as sequences for LP-WUSs. For example, as shown in FIG. 2, the sequence distance metrics between each respective pair of binary sequences may be greater than or equal to the first distance threshold 225-a (e.g., sequence distance metrics≥dₘᵢₙ). In other words, each sequence distance metric between each respective pair of binary sequences may satisfy the first distance threshold 225-a dₘᵢₙ by being greater than or equal to the first distance threshold 225-a.

In some aspects, the first distance threshold 225-a (dₘᵢₙ) may be based on a length of the set/universe of binary sequences 215. For instance, the first distance threshold 225-a may be determined by

$${d}_{min} \geq \frac{n}{2} ,$$

where n is the sequence length of at least one binary sequence within the set/universe of binary sequences 215 (e.g., average sequence length, minimum sequence length, maximum sequence length, etc.). In this example, first distance threshold 225 (dₘᵢₙ) may be greater than or equal to half of the length (e.g., average length, minimum length, maximum length) of the set/universe of binary sequences 215.

Additionally, or alternatively, the universe of binary sequences 215 may be generated/selected such that X-percentile (d_{X}) of pair-wise sequence distance metrics between respective pairs of binary sequences satisfy the first distance threshold 225-a (dₘᵢₙ) (e.g., d_{X} of the sequence distance metrics are greater than or equal to dₘᵢₙ). In other words, X % of the pair-wise sequence distance metrics between respective pairs of binary sequences satisfy the first distance threshold 225-a dₘᵢₙ, where 1-X % of the pair-wise sequence distance metrics fail to satisfy the first distance threshold 225-a dₘᵢₙ, where X may be pre-determined or signaled to be any percentage, such as X=1%, 10%, 0.01%, etc., and where the first distance threshold 225-a may be

$$\frac{n}{2} , \frac{n}{2} + 1 , \frac{n}{2} - 1 ,$$

etc., where n is the sequence length of at least one binary sequence within the set/universe of binary sequences 215.

In some implementations, the universe of binary sequences 215 may be generated/selected such that, for each binary sequence(s) in the universe of binary sequences 215, then there can be at most Y binary sequences in the universe of binary sequences 215 that exhibit a sequence distance metric from the binary sequence s which are below a distance threshold. In this example, Y may be pre-configured or signaled, where Y=1, 2, etc. In such cases, the UE 115-a may only be expected to compare received signals/RF waveforms 235 with the Y quantity of other binary sequences, instead of comparing to all other binary sequences in the universe of binary sequences 215 (if the set of binary sequences do not met the distance requirements).

In some aspects, the universe of binary sequences 215 may be generated (e.g., by the network entity 105-a and/or another network entity) using a matrix generator of a binary linear block code. For example, the universe of binary sequences 215 may be generated using a Golay code, a Reed Muller code, a Reed Solomon code, a Bose-Chaudhuri-Hocquenghem code, a Hamming code, a polar code, an LDPC code, or any combination thereof. Detailed examples of a Golay code and a Reed Muller code for generating the universe of binary sequences 215 will be further shown and described at the end of the FIG. 2 description.

For example, in the case of a binary linear block code, the generator matrix (e.g., k*n) of the linear block code may be predefined within the network, signaled to the respective devices, or both. In this example, the number of binary sequences 220 within the universe of binary sequences 215 that can be generated/supported by the code is 2^{k}. In additional or alternative implementations, the universe of binary sequences 215 may be generated using a sequence configuration of length 2^{m-1} using a length 31, 63, 127, etc. m-sequence, Gold sequence, Kasami sequence, or any combination thereof.

Additionally, or alternatively, the universe of binary sequences 215 may include a computer-generated list of binary WUS sequences. In this case, one or more sets of binary sequences may be explicitly defined and/or signaled by the network. In this example, the universe of binary sequences 215 may be indexed by: (1) a length of the binary sequence(s), and/or (2) the number/quantity of binary sequences in the universe of binary sequences 215. The set/universe of binary sequences 215 may be selected such that the minimum distance between the binary sequences satisfy some minimum distance requirement (e.g., first distance threshold 225-a, dₘᵢₙ).

In some aspects, the network may utilize a first sequence design (e.g., first set of sequences, or approaches to generate the universe of binary sequences 215) for a first sequence length, and use a second sequence design for a second length. As an example, the first sequence design and second sequence design may be generated using a first linear block code and a second linear block code, respectively. In another example, a first sequence design may include a linear block code, and a second sequence design may include a computer generated set of sequences. Additionally, a Golay code or Reed Muller code (e.g., first-order Reed-Muller code) may be used to generate the universe of binary sequences 215 for n=32. In particular, the wireless communications system 200 may reuse the NR Reed Muller code for the purpose of WUS sequence generation. Further, for n=64 and n=128, a Reed Muller code, a Gold code, and/or a binary M-sequence may be used to generate the universe of binary sequences 215 as long as the minimum distance requirement (e.g., first distance threshold 225-a) is satisfied. Additionally, or alternatively, the network could define the code for n=32. In such cases, for n>32 (e.g., n=64, n=128), the sequence may be repeated to the desired length.

In some implementations, the UE 115-a may be associated with (e.g., assigned) multiple binary sequences. In other words, in some implementations, the UE 115-a may receive a configuration or other indication from the network entity 105-a to monitor multiple binary sequences. For example, the network may configure multiple binary sequence indices for the UE 115-a to determine the multiple binary sequences that the UE 115-a is expected to monitor for WUSs.

In some cases, the control signaling 210 may be used to assign the UE 115-a with a first binary sequence 220 that is specific/unique to the UE 115-a, and an additional binary sequence that is associated with a group of UEs 115 including the UE 115-a. In this example, the group of UEs 115 may include UEs 115 that are within a cell supported by the network entity 105-a (e.g., cell-specific binary sequence), a certain geographical area, and the like. For instance, in some cases, the network entity 105-a may configure a default binary sequence (e.g., first binary sequence, Sequence 0, last sequence of the universe of binary sequences 215) that are assigned to (e.g., monitored by) all UEs 115 within the network. In this example, the network entity 105-a may additionally configure UE-specific sequences for each respective UE 115.

In some aspects, the control signaling 210 (e.g., RRC signaling, system information signaling, DCI signaling, MAC-CE signaling) may additionally indicate other information associated with WUSs, including a set of WUS monitoring occasions, scrambling sequence(s) associated with the UE 115-a and/or corresponding binary sequences, a second distance threshold 225 (e.g., dₜₕ) used to evaluate received RF waveforms 235, and the like.

For example, as shown in FIG. 2, the control signaling 210 may indicate a second distance threshold 225-b (e.g., dₜₕ) that is to be used by the UE 115-a to evaluate received RF waveforms 235/WUSs. In some aspects, the second distance threshold 225-b may control the false alarm rate and/or mis-detection rate. As such, in some implementations, the UE 115-a and/or the network entity 105-a may be configured to selectively modify the second distance threshold 225-b (e.g., dₜₕ) in order to strike a balance between the false alarm mis-detection rates.

In some implementations, the control signaling 210 may indicate additional or alternative parameters associated with the detection and/or evaluation of binary sequences, where the UE 115-a may be configured to use the additional/alternative parameters to evaluate received RF waveforms 235/binary sequence (instead of calculating the distances themselves). For example, the control signaling 210 may indicate a probability that binary sequences are transmitted, such as the probability of no RF waveforms 235 being transmitted, the probability of some valid RF waveform 235 being transmitted, or both. In this example, the UE 115-b may be configured to evaluate whether received RF waveforms 235 are associated with binary sequences assigned to the UE 115-a (e.g., compute sequence distance metrics for received RF waveforms 235) based on the indicated probabilities.

In some cases, the UE 115-a may enter a low-power mode or operational state. That is, the UE 115-a may transition from a regular or higher-power mode/operational state to a lower-power mode or operational state associated with a lower power consumption. For example, the UE 115-a may transition to an inactive or idle period of a DRX cycle. As noted previously herein, the UE 115-a may enter the low-power state or operational mode in order to reduce power consumption and conserve battery life. In some cases, the UE 115-a may enter the low-power operational state based on receiving the control signaling 210.

The UE 115-a may monitor WUS monitoring occasions while in the low-power operational state. In some cases, the UE 115-a may use a designated “wake-up receiver” to monitor the set of WUS monitoring occasions which were configured via the control signaling 210 for WUSs that are used by the network to indicate when there is message traffic 240 waiting to be delivered to the UE 115-a. As such, the UE 115-a may monitor the WUS monitoring occasions based on receiving the control signaling 210 at 305, entering the low-power operational state, or both.

In some aspects, the network entity 105-a may identify message traffic 240 (e.g., PDSCH message(s)) that are to be transmitted to the UE 115-a. Moreover, the network entity 105-a may identify that the UE 115-a is in the low-power operational state, and is therefore unable to receive the message traffic 240. In some cases, the network entity 105-a may identify that the UE 115-a is in the low-power state based on explicit signaling from the UE 115-a, based on CDRX cycle associated with the UE 115-a, or both.

Upon identifying message traffic 240 that is to be transmitted to the UE 115-a, the network entity 105-a may identify an RF waveform 235 corresponding to the UE 115-a. The RF waveform 235 may include, but is not limited to, an OOK waveform, an FSK waveform, and the like. In particular, the network entity 105-a may identify an RF waveform 235 corresponding to the first binary sequence 220 (or another binary sequence) associated with (e.g., assigned to) the UE 115-a.

In some implementations, the network entity 105-a may reference a table or other data object that maps the universe of binary sequences 215 to a corresponding of RF waveforms 235 and corresponding receiver devices. For example, in some cases, the network entity 105-a may reference a table or other data object that maps the universe of binary sequences 215 to a corresponding of RF waveforms 235 and corresponding receiver devices using a UE ID associated with the UE 115-a to determine the first binary sequence 220 corresponding to the UE 115-a, and an RF waveform 235 corresponding to the first binary sequence 220.

In some aspects, the UE 115-a may receive an RF waveform 235 (e.g., WUS) from the network entity 105-a. In particular, the UE 115-a may receive the RF waveform 235 within a WUS monitoring occasion included within the set of WUS monitoring occasions configured via the control signaling 210, and based on monitoring the set of WUS monitoring occasions. Moreover, the network entity 105-a may transmit the RF waveform 235 (e.g., WUS) based on identifying message traffic 240 to be delivered to the UE 115-a, identifying the RF waveform 235, or both. As noted previously herein, the RF waveform 235 may include, but is not limited to, an OOK waveform, an FSK waveform, and the like.

In some aspects, the network entity 105-a may generate the RF waveform 235 based on (e.g., using, in accordance with) a scrambling sequence. In some aspects, scrambling sequences may be used to randomize the transmitted sequences/RF waveforms to avoid long durations of zeros and ones from the transmitter. In some aspects, the scrambling sequence may be UE-specific (e.g., associated with the first binary sequence 220), cell-specific (e.g., used for all UEs 115 within a serving cell), or both. In some cases, the scrambling sequence corresponding to the UE 115-a/first binary sequence 220 may be pre-configured at the UE 115-a, signaled to the UE 115-a (e.g., via the control signaling 210), or both. In some implementations, the scrambling sequences may be determined based on a number of parameters, factors, or characteristics, including, but not limited to, a starting slot/symbol/frame/subframe index of the LP-WUS occasion, a beam index (e.g., in cases where the LP-WUS is transmitted over different beams), a cell ID, an identifier associated with the UE 115-a (e.g., UE ID), and the like.

For example, WUSs (e.g., RF waveforms) generated from the linear code/computer-generated binary sequence may be denoted by b₀, . . . , b_{N-1}, and scrambling sequences may be denoted by s₀, . . . , s_{N-1}. In this example, the actual sequence/RF waveform 235 (cᵢ) transmitted by the network entity 105-a may be represented as cᵢ=bᵢ⊕sᵢ. In some aspects, the scrambling sequence may be based on a Gold sequence (e.g., pseudo-random sequence, PN sequence). For instance, in some cases, a scrambling sequence may be determined/generated based on a Gold sequence, where the seed of the Gold sequence is determined based on a starting slot/symbol/frame/subframe index of the LP-WUS occasion, a beam index (e.g., in cases where the LP-WUS is transmitted over different beams), a cell ID, a UE ID, and the like.

In some aspects, the UE 115-a may generate a second binary sequence (e.g., binary sequence 230-a or 230-b) associated with the received RF waveform 235. For example, as described previously herein, the UE 115-a may generate one bit of the second binary sequence 230 for each symbol of the received RF waveform 235. In some cases, the UE 115-a may generate the second binary sequence 230 using a wake-up component or other low-power component of the UE 115-a (which is separate from a main receiver or baseband component).

In some cases, the UE 115-a may be configured to descramble the received RF waveform 235 prior to generating the second binary sequence 230. For example, in some cases, the UE 115-a may be configured to generate a modified version of the received RF waveform 235, such as by descrambling the received RF waveform 235 based on the pre-configured or signaled scrambling sequence. In this example, the UE 115-a may be configured to generate the second binary sequence 230 based on the modified version (e.g., descrambled version) of the received RF waveform 235.

Subsequently, the UE 115-a may be configured to compare a sequence distance metric associated with the second binary sequence 230 to a second distance threshold 225 (e.g., dₜₕ). In particular, the UE 115-a may be configured to calculate a sequence distance metric between the second binary sequence 230 associated with the received RF waveform 235 and the first binary sequence 220 associated with (e.g., assigned to) the UE 115-a. In some cases, a “sequence distance metric” may be calculated by comparing the respective binary sequences to calculate the number/quantity of digits/integers that vary between the respective binary sequences. For example, a Hamming distance between binary sequences A=0101 and B=0110 may be two, as the last two integers between the respective binary sequences are different from one another (e.g., “01” in sequence A, and “10” in sequence B).

Moreover, in cases where the UE 115-a is associated with or assigned multiple binary sequences (e.g., a UE-specific binary sequence, and a cell-based binary sequence), the UE 115-a may be configured to calculate multiple separate sequence distance metrics, and compare the generated sequence distance metrics to the second distance threshold 225 (e.g., dₜₕ).

The UE 115-a may determine whether the received RF waveform 235 is associated with the first binary sequence 220 associated with (e.g., assigned to) the UE 115-a (and/or another binary sequence assigned to the UE 115-a). The UE 115-a may perform the determination based on receiving the control signaling 210, receiving the RF waveform 235, generating the second binary sequence 230, comparing the sequence distance metric(s) to the second distance threshold 225-b, or any combination thereof.

In some cases, the UE 115-a may determine that the received RF waveform 235 is associated with the first binary sequence 220 if the second binary sequence 230 associated with the RF waveform 235 is sufficiently close or similar to the first binary sequence 220. That is, the UE 115-a may determine that the received RF waveform 235 is associated with the first binary sequence 220 if a sequence distance metric between the first binary sequence 220 and the second binary sequence 230 is less than or equal to the second distance threshold 225 (e.g., satisfied if d_{sequence distance}≤dₜₕ)

Stated differently, the UE 115-a (e.g., receiver device) may compare the Hamming distance d(ŷ,s) between the received signal § (e.g., RF waveform 235) with the first binary sequence 220 assigned to the UE 115-a, and may detect a WUS if d(ŷ,s)≤dₜₕ. For instance, the UE 115-a may generate the second binary sequence 230-a associated with the received RF waveform 235, and may determine that a sequence distance metric between the second binary sequence 230-a and the first binary sequence 220 is less than the second distance threshold 225-b. As such, in this example, the UE 115-a may detect a WUS.

Comparatively, the UE 115-a may determine that the received RF waveform 235 is not associated with the first binary sequence 220 if the second binary sequence associated with the RF waveform 235 is not sufficiently close or similar to the first binary sequence 220. That is, the UE 115-a may determine that the received RF waveform 235 is not associated with the first binary sequence 220 if a sequence distance metric between the first binary sequence 220 and the second binary sequence is greater than the second distance threshold 225 (e.g., not satisfied if d_{sequence distance}>dₜₕ).

Stated differently, the UE 115-a (e.g., receiver device) may compare the Hamming distance d(ŷ,s) between the received signal ŷ (e.g., RF waveform 235) with the first binary sequence 220 assigned to the UE 115-a, and may not detect a WUS if d(ŷ,s)>dₜₕ. For instance, the UE 115-a may generate the second binary sequence 230-b associated with the received RF waveform 235, and may determine that a sequence distance metric between the second binary sequence 230-b and the first binary sequence 220 is greater than the second distance threshold 225-b. As such, in this example, the UE 115-a may determine that the received RF waveform 235 is not intended as a WUS for the UE 115-a.

It is noted herein that a single RF waveform 235 may be used as a WUS for multiple different receiver devices. For example, as shown in FIG. 2, the second distance threshold 225-b for two separate binary sequences may overlap. In this regard, the decision regions for the receiver devices corresponding to the respective binary sequences may overlap. Further, as compared to some conventional WUS techniques in which receiver devices may be required to compare RF waveforms 235 to each binary sequence within the universe of binary sequences 215, the UE 115-a may only be expected to compare received RF waveforms 235 to binary sequences assigned to the UE 115-a. In this regard, the UE 115-a may only need to determine whether its own binary sequence(s) 220 have been transmitted, and does not need to determine which specific binary sequence from the universe of binary sequences 215 has been transmitted in the event the RF waveform 235 is associated with a different binary sequence. In this regard, aspects of the present disclosure may simplify processing expectations at receiver devices.

In cases where the UE 115-a determines that the received RF waveform 235 is not associated with the first binary sequence 220 (e.g., in cases where the received RF waveform 235 is associated with the second binary sequence 230-b), the UE 115-a may remain in the low-power operational state.

Conversely, in cases where the UE 115-a determines that the received RF waveform 235 is associated with the first binary sequence 220 (e.g., in cases where the received RF waveform 235 is associated with the second binary sequence 230-a), the UE 115-a may transition from the low-power operational state to a higher-power operational state. In particular, the UE 115-a may transition to the higher-power operational state based on determining that the received RF waveform 235 is associated with the first binary sequence 220 (or another binary sequence) associated with/assigned to the UE 115-a. For example, the UE 115-a may transition from an idle/inactive period of a DRX cycle to an active period of the DRX cycle. In some implementations, the UE 115-a may indicate, to the network entity 105-a, that the UE 115-a has transitioned to the higher-power operational state.

Subsequently, the UE 115-a may receive message traffic 240 (e.g., PDSCH message(s)) from the network entity 105-a. The UE 115-a may receive the message traffic 240 based on receiving the RF waveform 235, determining that the RF waveform 235 is associated with the first binary sequence 220, transitioning to the higher-power operational state, or any combination thereof.

In some implementations, aspects of the present disclosure may reduce a false alarm rate associated with WUSs. For example, the WUS sequence (e.g., first binary sequence 220) for the UE 115-a may be represented as s. In a first case, the network entity 105-a may not send any WUS (e.g., the RF waveform 235 does not include a wake-up indication). In this case, the false alarm rate (FA) received signal/RF waveform 235 may be modeled as a Bernoulli binary sequence, as illustrated in Equation 4 below:

$$F A = \frac{v o l ( B ( d , s ) )}{v o l ( {F}_{2}^{n} )} = \frac{{2}^{n}}{{\sum }_{t = 0}^{{d}_{th}} ( \begin{matrix}n \\ k\end{matrix} )} \qquad ( 4 )$$

Referring to Equation 4, with a binary sequence length of n=32 and a second distance threshold 225-b of dₜₕ=9, the false alarm rate may be FA=0.01.

In a second case, the network entity 105-a may transmit a WUS for another receiver device. In other words, the RF waveform 235 may include a wake-up indication for another receiver device, and may be represented as s′. In this case, the false alarm rate FA may be represented by Equation 5 below:

$$F A = P r o b [ {d}_{min} - A + B < {d}_{th} ] \qquad ( 5 )$$

where A and B denote the number of sign-flips (due to noise) in the first dₘᵢₙ and last n−dₘᵢₙ bits, respectively.

Comparing these false alarm rate for the two cases illustrated in Equations 4 and 5 above, it may be seen that the false alarm rate for the first case (e.g., Equation 4) is smaller than the second case (e.g., Equation 5) as long as

$${d}_{min} \geq \frac{n}{2} , and {d}_{th} < \frac{n}{2} .$$

In this regard, as long as

$${d}_{min} \geq \frac{n}{2} ,$$

the performance (as illustrated by false alarm rates vs. mis-detection rates) may be independent of the code/sequence design. As such, it suffices to choose dₜₕ such that false alarm rate under the first case, as illustrated in Equation 4, meets a desired/expected false alarm target or threshold (a first order Reed Muller code (Hadamard sequence) and m-sequence may both satisfy such properties/restrictions).

A detailed example of a Golay code for generating the universe of binary sequences 215 may be illustrative. In some cases, the WUS information bits input to the channel coding block may be dented by a₀, . . . , aₖ₋₁, where k is the number of information bits (e.g., k=log₂(#sequences)), and where a₀, . . . , aₖ₋₁ may be the binary expression of the WUS sequence index for an associated UE 115/UE group. The k control information bits may be encoded using the (k,n) linear code.

In the case of a modified Golay code, after encoding, the WUS information bits may be denoted by b₀, . . . , bₙ₋₁. For n=24 or n=32, the encoded bits are represented by Equation 6 below:

$${b}_{i} = \{ \begin{matrix}{a}_{i} , i < k \\ {\sum }_{m = 0}^{k - 1} {a}_{m} {M}_{i , m} mod 2 , i \geq k\end{matrix} i = 0 , … , n - 1 \qquad ( 6 )$$

For n=20, the coded bits are calculated by Equation 7 below:

$${b}_{i} = \{ \begin{matrix}{a}_{i} , i < k \\ {\sum }_{m = 0}^{k - 1} {a}_{m} {M}_{u , m} mod 2 , i \geq k , u = \{ \begin{matrix}i , i < 8 \\ i + 4 , i \geq 9\end{matrix} ,\end{matrix} i = 0 , … , n - 1 \qquad ( 7 )$$

A basic generator matrix for linear block code based on the Golay code described above is illustrated in Table 1 below:

TABLE 1
Basic generator matrix for linear block code based on Golay code

| i | M_{i, 0} | M_{i, 1} | M_{i, 2} | M_{i, 3} | M_{i, 4} |
|---|---|---|---|---|---|
| 0 | 1 | 0 | 0 | 0 | 0 |
| 1 | 0 | 1 | 0 | 0 | 0 |
| 2 | 0 | 0 | 1 | 0 | 0 |
| 3 | 1 | 1 | 1 | 1 | 0 |
| 4 | 0 | 0 | 1 | 0 | 1 |
| 5 | 1 | 0 | 0 | 1 | 1 |
| 6 | 0 | 1 | 0 | 1 | 1 |
| 7 | 1 | 1 | 1 | 0 | 0 |
| 8 | 1 | 1 | 0 | 0 | 1 |
| 9 | 1 | 0 | 1 | 0 | 1 |
| 10 | 1 | 0 | 1 | 1 | 1 |
| 11 | 0 | 1 | 1 | 1 | 1 |
| 12 | 1 | 0 | 0 | 0 | 1 |
| 13 | 0 | 0 | 0 | 1 | 1 |
| 14 | 0 | 0 | 1 | 1 | 1 |
| 15 | 0 | 1 | 1 | 1 | 0 |
| 16 | 1 | 1 | 1 | 0 | 1 |
| 17 | 1 | 1 | 0 | 1 | 1 |
| 18 | 1 | 0 | 1 | 1 | 0 |
| 19 | 0 | 1 | 1 | 0 | 1 |
| 20 | 1 | 1 | 0 | 1 | 0 |
| 21 | 1 | 0 | 1 | 0 | 0 |
| 22 | 0 | 1 | 0 | 0 | 0 |
| 23 | 1 | 1 | 1 | 1 | 1 |
| 24 | 0 | 0 | 1 | 1 | 0 |
| 25 | 0 | 1 | 0 | 0 | 1 |
| 26 | 0 | 1 | 0 | 1 | 0 |
| 27 | 0 | 1 | 1 | 0 | 0 |
| 28 | 0 | 1 | 1 | 0 | 1 |
| 29 | 1 | 0 | 0 | 1 | 0 |
| 30 | 1 | 1 | 0 | 0 | 0 |
| 31 | 1 | 1 | 1 | 1 | 0 |

In the case of a Reed Muller code that may be used to generate the universe of binary sequences 215, for 3≤k≤11, the code block may be encoded by Equation 8 below:

$${b}_{i} = {\sum }_{m = 0}^{k - 1} {a}_{m} {M}_{i , m} mod 2 \qquad ( 8 )$$

where i=0, . . . , k−1, n=32, and M_{i,m} represents the basis sequences, which may be defined by the network, as illustrated in Table 2 below:

TABLE 2
Basis sequences for (32, k) code

| i | M_{i, 0} | M_{i, 1} | M_{i, 2} | M_{i, 3} | M_{i, 4} | M_{i, 5} | M_{i, 6} | M_{i, 7} | M_{i, 8} | M_{i, 9} | M_{i, 10} |
|---|---|---|---|---|---|---|---|---|---|---|---|
| 0 | 1 | 1 | 0 | 0 | 0 | 0 | 0 | 0 | 0 | 0 | 1 |
| 1 | 1 | 1 | 1 | 0 | 0 | 0 | 0 | 0 | 0 | 1 | 1 |
| 2 | 1 | 0 | 0 | 1 | 0 | 0 | 1 | 0 | 1 | 1 | 1 |
| 3 | 1 | 0 | 1 | 1 | 0 | 0 | 0 | 0 | 1 | 0 | 1 |
| 4 | 1 | 1 | 1 | 1 | 0 | 0 | 0 | 1 | 0 | 0 | 1 |
| 5 | 1 | 1 | 0 | 0 | 1 | 0 | 1 | 1 | 1 | 0 | 1 |
| 6 | 1 | 0 | 1 | 0 | 1 | 0 | 1 | 0 | 1 | 1 | 1 |
| 7 | 1 | 0 | 0 | 1 | 1 | 0 | 0 | 1 | 1 | 0 | 1 |
| 8 | 1 | 1 | 0 | 1 | 1 | 0 | 0 | 1 | 0 | 1 | 1 |
| 9 | 1 | 0 | 1 | 1 | 1 | 0 | 1 | 0 | 0 | 1 | 1 |
| 10 | 1 | 0 | 1 | 0 | 0 | 1 | 1 | 1 | 0 | 1 | 1 |
| 11 | 1 | 1 | 1 | 0 | 0 | 1 | 1 | 0 | 1 | 0 | 1 |
| 12 | 1 | 0 | 0 | 1 | 0 | 1 | 0 | 1 | 1 | 1 | 1 |
| 13 | 1 | 1 | 0 | 1 | 0 | 1 | 0 | 1 | 0 | 1 | 1 |
| 14 | 1 | 0 | 0 | 0 | 1 | 1 | 0 | 1 | 0 | 0 | 1 |
| 15 | 1 | 1 | 0 | 0 | 1 | 1 | 1 | 1 | 0 | 1 | 1 |
| 16 | 1 | 1 | 1 | 0 | 1 | 1 | 1 | 0 | 0 | 1 | 0 |
| 17 | 1 | 0 | 0 | 1 | 1 | 1 | 0 | 0 | 1 | 0 | 0 |
| 18 | 1 | 1 | 0 | 1 | 1 | 1 | 1 | 1 | 0 | 0 | 0 |
| 19 | 1 | 0 | 0 | 0 | 0 | 1 | 1 | 0 | 0 | 0 | 0 |
| 20 | 1 | 0 | 1 | 0 | 0 | 0 | 1 | 0 | 0 | 0 | 1 |
| 21 | 1 | 1 | 0 | 1 | 0 | 0 | 0 | 0 | 0 | 1 | 1 |
| 22 | 1 | 0 | 0 | 0 | 1 | 0 | 0 | 1 | 1 | 0 | 1 |
| 23 | 1 | 1 | 1 | 0 | 1 | 0 | 0 | 0 | 1 | 1 | 1 |
| 24 | 1 | 1 | 1 | 1 | 1 | 0 | 1 | 1 | 1 | 1 | 0 |
| 25 | 1 | 1 | 0 | 0 | 0 | 1 | 1 | 1 | 0 | 0 | 1 |
| 26 | 1 | 0 | 1 | 1 | 0 | 1 | 0 | 0 | 1 | 1 | 0 |
| 27 | 1 | 1 | 1 | 1 | 0 | 1 | 0 | 1 | 1 | 1 | 0 |
| 28 | 1 | 0 | 1 | 0 | 1 | 1 | 1 | 0 | 1 | 0 | 0 |
| 29 | 1 | 0 | 1 | 1 | 1 | 1 | 1 | 1 | 1 | 0 | 0 |
| 30 | 1 | 1 | 1 | 1 | 1 | 1 | 1 | 1 | 1 | 1 | 1 |
| 31 | 1 | 0 | 0 | 0 | 0 | 0 | 0 | 0 | 0 | 0 | 0 |

In the context of WUS application, it suffices to take the first k columns from Table 2 above for encoding the WUS binary sequences (e.g., k=4, 5).

For pseudo-random sequence generation, generic pseudo-random sequences may be defined by a length-31 Gold sequence. The output sequence c(n) of length M_{PN} may be defined by Equations 9-11 below:

$$c ( n ) = ( {x}_{1} ( n + {N}_{c} ) + {x}_{2} ( n + {N}_{c} ) ) mod 2 \qquad ( 9 )$$

$${x}_{1} ( n + 31 ) = ( {x}_{1} ( n + 3 ) + {x}_{1} ( n ) ) mod 2 \qquad ( 9 )$$

$${x}_{2} ( n + 31 ) = ( {x}_{2} ( n + 3 ) + {x}_{2} ( n + 2 ) + {x}_{2} ( n + 1 ) + {x}_{2} ( n ) ) mod 2 \qquad ( 11 )$$

where n=0, 1, . . . , M_{PN}−1, where N_{C}=1600, and the first m-sequence x₁(n) may be initialized with x₁(0)=1, x₁(n)=0, n=1, 2, . . . , 30. The initialization of the second m-sequence, x₂(n), is denoted by

$${c}_{init} = {\sum }_{i = 0}^{30} {x}_{2} ( i ) \cdot {2}^{i} {M}_{i , m}$$

with the value depending on the application of the sequence.

Techniques described herein may enable the use of binary WUS sequences that reduce processing requirements and complexity at receiver devices. In particular, by generating a set of binary sequences that each exhibit a minimum distance threshold 225 from one another, aspects of the present disclosure may enable the UE 115-a to compare binary sequences associated with received RF waveforms 235 to the one or more binary sequences assigned to the receiver device. In other words, techniques described herein may reduce or eliminate the need for the UE 115-a to compare binary sequences to every binary sequence within the universe of binary sequences 215 used by the network. As such, techniques described herein may reduce power consumption associated with processing WUSs at the UE 115-a, and improve power-saving capabilities of receiver devices operating in lower-power states. Moreover, the binary WUS sequence configurations described herein may reduce false alarms and mis-detections for WUSs, further reducing power consumption at the UE 115-a, improving the efficiency and reliability of WUSs, and leading to a more efficient use of wireless resources.

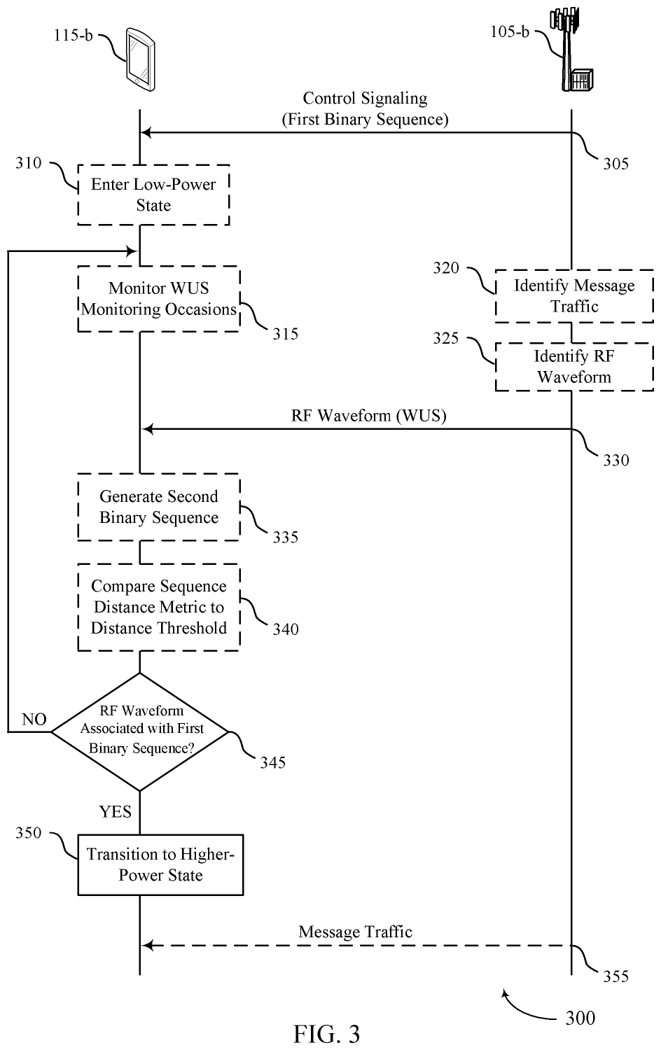

FIG. 3 illustrates an example of a process flow 300 that supports techniques for binary WUS sequences in accordance with one or more aspects of the present disclosure. In some examples, aspects of the process flow 300 may implement, or be implemented by, aspects of the wireless communications system 100, the wireless communications system 200, or both. In particular, the process flow 300 illustrates signaling used to implement binary WUS sequence configurations, as described with respect to FIG. 1-2.

The process flow 300 may include a UE 115-b and a network entity 105-b, which may be examples of UEs 115, network entities 105, and other wireless devices described with reference to FIGS. 1-2. For example, the UE 115-b and the network entity 105-b illustrated in FIG. 3 may be examples of the UE 115-a and the network entity 105-a, respectively, as shown and described in FIG. 2.

In some examples, the operations illustrated in process flow 300 may be performed by hardware (e.g., including circuitry, processing blocks, logic components, and other components), code (e.g., software) executed by a processor, or any combination thereof. Alternative examples of the following may be implemented, where some steps are performed in a different order than described or are not performed at all. In some cases, steps may include additional features not mentioned below, or further steps may be added.

At 305, the UE 115-b may receive, from the network entity 105-b, control signaling indicating a first binary sequence corresponding to the UE 115-b. In other words, the network entity 105-a may “assign” the first binary sequence to the UE 115-b. In some aspects, the first binary sequence may be included within a set of binary sequences used within the network (e.g., included within a universe of binary sequences), where sequence distance metrics (e.g., Hamming distance property metrics) between each respective pair of binary sequences of the set/universe of binary sequences satisfies a first distance threshold.

For example, as shown in FIG. 2, the sequence distance metrics between each respective pair of binary sequences may be greater than or equal to the first distance threshold 225-a (e.g., sequence distance metrics≥dₘᵢₙ). In other words, each sequence distance metric between each respective pair of binary sequences may satisfy the first distance threshold dₘᵢₙ by being greater than or equal to the first distance threshold. In some aspects, the first distance threshold (dₘᵢₙ) may be based on a length of the set/universe of binary sequences. For instance, the first distance threshold dₘᵢₙ may be determined by

$${d}_{min} \geq \frac{n}{2} ,$$

where n is the sequence length of at least one binary sequence within the set/universe of binary sequences (e.g., average sequence length, minimum sequence length, maximum sequence length, etc.). In this example, first distance threshold dₘᵢₙ) may be greater than or equal to half of the length (e.g., average length, minimum length, maximum length) of the set/universe of binary sequences.

In some aspects, the universe of binary sequences may be generated (e.g., by the network entity 105-b and/or another network entity) using a matrix generator of a binary linear block code. For example, the universe of binary sequences may be generated using a Golay code, a Reed Muller code, a Reed Solomon code, a Bose-Chaudhuri-Hocquenghem code, a Hamming code, a polar code, an LDPC code, or any combination thereof.

In some implementations, the UE 115-b may be associated with (e.g., assigned) multiple binary sequences. For example, in some cases, the UE 115-b may be assigned a first binary sequence that is specific/unique to the UE 115-b, and an additional binary sequence that is associated with a group of UEs 115 including the UE 115-b. In this example, the group of UEs 115 may include UEs 115 that are within a cell supported by the network entity 105-b (e.g., cell-specific binary sequence), a certain geographical area, and the like.

In some aspects, the control signaling (e.g., RRC signaling, system information signaling, DCI signaling, MAC-CE signaling) may additionally indicate other information associated with WUSs, including a set of WUS monitoring occasions, scrambling sequence(s) associated with the UE 115-b and/or corresponding binary sequences, a second distance threshold (e.g., dₜₕ) used to evaluate received RF waveforms, and the like. For example, the control signaling may indicate a second distance threshold that is to be used by the UE 115-b to evaluate received RF waveforms/WUSs. For example, as shown in FIG. 2, the UE 115-b may receive an indication of the second distance threshold 225-b (e.g., dₘᵢₙ) that the UE 115-b will use to evaluate received WUSs.

At 310, the UE 115-b may enter a low-power mode or operational state. That is, the UE 115-b may transition from a regular or higher-power mode/operational state to a lower-power mode or operational state associated with a lower power consumption. For example, the UE 115-b may transition to an inactive or idle period of a DRX cycle. As noted previously herein, the UE 115-b may enter the low-power state or operational mode in order to reduce power consumption and conserve battery life. In some cases, the UE 115-b may enter the low-power operational state at 310 based on receiving the control signaling at 305.

At 315, the UE 115-b may monitor WUS monitoring occasions while in the low-power operational state. In some cases, the UE 115-b may use a designated “wake-up receiver” to monitor the set of WUS monitoring occasions which were configured via the control signaling at 305 for WUSs that are used by the network to indicate when there is message traffic waiting to be delivered to the UE 115-b. As such, the UE 115-b may monitor the WUS monitoring occasions at 315 based on receiving the control signaling at 305, entering the low-power operational state at 310, or both.

At 320, the network entity 105-b may identify message traffic (e.g., PDSCH message(s)) that are to be transmitted to the UE 115-b. Moreover, the network entity 105-b may identify that the UE 115-b is in the low-power operational state, and is therefore unable to receive the message traffic. In some cases, the network entity 105-b may identify that the UE 115-b is in the low-power state based on explicit signaling from the UE 115-b, based on CDRX cycle associated with the UE 115-b, or both.

At 325, the network entity 105-b may identify an RF waveform corresponding to the UE 115-b. The RF waveform may include, but is not limited to, an OOK waveform, an FSK waveform, and the like. In particular, the network entity 105-b may identify an RF waveform corresponding to the first binary sequence (or another binary sequence) associated with (e.g., assigned to) the UE 115-b.

For example, in some cases, the network entity 105-b may reference a table or other data object that maps the universe of binary sequences to a corresponding of RF waveforms and corresponding receiver devices. For instance, the network entity 105-b may index or reference a data object/table using a UE ID associated with the UE 115-b to determine the first binary sequence corresponding to the UE 115-b, and an RF waveform corresponding to the first binary sequence.

At 330, the UE 115-b may receive an RF waveform (e.g., WUS) from the network entity 105-b. In particular, the UE 115-b may receive the RF waveform within a WUS monitoring occasion included within the set of WUS monitoring occasions configured at 305, and based on monitoring the set of WUS monitoring occasions at 315. Moreover, the network entity 105-b may transmit the RF waveform (e.g., WUS) at 330 based on identifying message traffic to be delivered to the UE 115-b at 320, identifying the RF waveform at 325, or both. As noted previously herein, the RF waveform may include, but is not limited to, an OOK waveform, an FSK waveform, and the like.

In some aspects, the network entity 105-b may generate the RF waveform based on (e.g., using, in accordance with) a scrambling sequence. In particular, the network entity 105-b may generate the RF waveform in accordance with a scrambling sequence associated with the first binary sequence associated with the UE 115-b. In some cases, the scrambling sequence corresponding to the UE 115-b/first binary sequence may be pre-configured at the UE 115-b, signaled to the UE 115-b (e.g., via the control signaling at 305), or both.

At 335, the UE 115-b may generate a second binary sequence associated with the received RF waveform. For example, as described previously herein, the UE 115-b may generate one bit of the second binary sequence for each symbol of the received RF waveform. In some cases, the UE 115-b may generate the second binary sequence using a wake-up component or other low-power component of the UE 115-b (which is separate from a main receiver or baseband component).

In some cases, the UE 115-b may be configured to descramble the received RF waveform prior to generating the second binary sequence. For example, in some cases, the UE 115-b may be configured to generate a modified version of the received RF waveform, such as by descrambling the received RF waveform based on the pre-configured or signaled scrambling sequence. In this example, the UE 115-b may be configured to generate the second binary sequence based on the modified version (e.g., descrambled version) of the received RF waveform.

At 340, the UE 115-b may be configured to compare a sequence distance metric associated with the second binary sequence to a second distance threshold (e.g., dₜₕ). In particular, the UE 115-b may be configured to calculate a sequence distance metric between the second binary sequence associated with the received RF waveform and the first binary sequence associated with (e.g., assigned to) the UE 115-b. Moreover, in cases where the UE 115-b is associated with or assigned multiple binary sequences (e.g., a UE-specific binary sequence, and a cell-based binary sequence), the UE 115-b may be configured to calculate multiple separate sequence distance metrics, and compare the generated sequence distance metrics to the second distance threshold (e.g., dₜₕ).

At 345, the UE 115-b may determine whether the received RF waveform is associated with the first binary sequence associated with (e.g., assigned to) the UE 115-b (and/or another binary sequence assigned to the UE 115-b). The UE 115-b may perform the determination at 345 based on receiving the control signaling at 305, receiving the RF waveform at 330, generating the second binary sequence at 335, comparing the sequence distance metric(s) to the second distance threshold at 340, or any combination thereof.

In some cases, the UE 115-b may determine that the received RF waveform is associated with the first binary sequence if the second binary sequence associated with the RF waveform is sufficiently close or similar to the first binary sequence. That is, the UE 115-b may determine that the received RF waveform is associated with the first binary sequence if a sequence distance metric between the first binary sequence and the second binary sequence is less than or equal to the second distance threshold (e.g., satisfied if d_{sequence distance}≤dₜₕ).

Comparatively, the UE 115-b may determine that the received RF waveform is not associated with the first binary sequence if the second binary sequence associated with the RF waveform is not sufficiently close or similar to the first binary sequence. That is, the UE 115-b may determine that the received RF waveform is not associated with the first binary sequence if a sequence distance metric between the first binary sequence and the second binary sequence is greater than the second distance threshold (e.g., not satisfied if d_{sequence distance}>dₜₕ).

In cases where the UE 115-b determines that the received RF waveform is not associated with the first binary sequence (or another binary sequence assigned to the UE 115-b) (e.g., step 345=NO), the UE 115-b may remain in the low-power operational state, and the process flow 300 may return to step 315. Conversely, in cases where the UE 115-b determines that the received RF waveform is associated with the first binary sequence (or another binary sequence assigned to the UE 115-b) (e.g., step 345=YES), the process flow 300 may proceed to step 350.

At 350, the UE 115-b may transition from the low-power operational state to a higher-power operational state. In particular, the UE 115-b may transition to the higher-power operational state at 350 based on determining that the received RF waveform is associated with the first binary sequence (or another binary sequence) associated with/assigned to the UE 115-b. For example, the UE 115-b may transition from an idle/inactive period of a DRX cycle to an active period of the DRX cycle. In some implementations, the UE 115-b may indicate, to the network entity 105-b, that the UE 115-b has transitioned to the higher-power operational state.

At 355, the UE 115-b may receive message traffic (e.g., PDSCH message(s)) from the network entity 105-b. The UE 115-b may receive the message traffic at 355 based on receiving the RF waveform at 330, determining that the RF waveform is associated with the first binary sequence at 345, transitioning to the higher-power operational state at 350, or any combination thereof.

Techniques described herein may enable the use of binary WUS sequences that reduce processing requirements and complexity at receiver devices. In particular, by generating a set of binary sequences that each exhibit a minimum distance threshold from one another, aspects of the present disclosure may enable the UE 115-b to compare binary sequences associated with received RF waveforms to the one or more binary sequences assigned to the receiver device. In other words, techniques described herein may reduce or eliminate the need for the UE 115-b to compare binary sequences to every binary sequence within the universe of binary sequences used by the network. As such, techniques described herein may reduce power consumption associated with processing WUSs at the UE 115-b, and improve power-saving capabilities of receiver devices operating in lower-power states. Moreover, the binary WUS sequence configurations described herein may reduce false alarms and mis-detections for WUSs, further reducing power consumption at the UE 115-b, improving the efficiency and reliability of WUSs, and leading to a more efficient use of wireless resources.

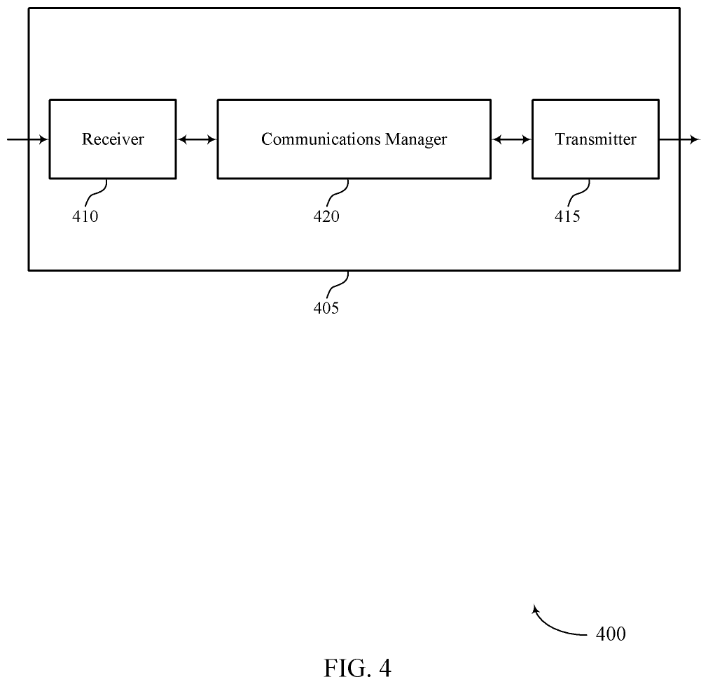

FIG. 4 shows a block diagram 400 of a device 405 that supports techniques for binary WUS sequences in accordance with one or more aspects of the present disclosure. The device 405 may be an example of aspects of a UE 115 as described herein. The device 405 may include a receiver 410, a transmitter 415, and a communications manager 420. The device 405 may also include a processor. Each of these components may be in communication with one another (e.g., via one or more buses).

The receiver 410 may provide a means for receiving information such as packets, user data, control information, or any combination thereof associated with various information channels (e.g., control channels, data channels, information channels related to techniques for binary WUS sequences). Information may be passed on to other components of the device 405. The receiver 410 may utilize a single antenna or a set of multiple antennas.

The transmitter 415 may provide a means for transmitting signals generated by other components of the device 405. For example, the transmitter 415 may transmit information such as packets, user data, control information, or any combination thereof associated with various information channels (e.g., control channels, data channels, information channels related to techniques for binary WUS sequences). In some examples, the transmitter 415 may be co-located with a receiver 410 in a transceiver module. The transmitter 415 may utilize a single antenna or a set of multiple antennas.

The communications manager 420, the receiver 410, the transmitter 415, or various combinations thereof or various components thereof may be examples of means for performing various aspects of techniques for binary WUS sequences as described herein. For example, the communications manager 420, the receiver 410, the transmitter 415, or various combinations or components thereof may support a method for performing one or more of the functions described herein.

In some examples, the communications manager 420, the receiver 410, the transmitter 415, or various combinations or components thereof may be implemented in hardware (e.g., in communications management circuitry). The hardware may include a processor, a digital signal processor (DSP), a central processing unit (CPU), a graphics processing unit (GPU), an application-specific integrated circuit (ASIC), a field-programmable gate array (FPGA) or other programmable logic device, a microcontroller, discrete gate or transistor logic, discrete hardware components, or any combination thereof configured as or otherwise supporting a means for performing the functions described in the present disclosure. In some examples, a processor and memory coupled with the processor may be configured to perform one or more of the functions described herein (e.g., by executing, by the processor, instructions stored in the memory).

Additionally, or alternatively, in some examples, the communications manager 420, the receiver 410, the transmitter 415, or various combinations or components thereof may be implemented in code (e.g., as communications management software) executed by a processor. If implemented in code executed by a processor, the functions of the communications manager 420, the receiver 410, the transmitter 415, or various combinations or components thereof may be performed by a general-purpose processor, a DSP, a CPU, a GPU, an ASIC, an FPGA, a microcontroller, or any combination of these or other programmable logic devices (e.g., configured as or otherwise supporting a means for performing the functions described in the present disclosure).

In some examples, the communications manager 420 may be configured to perform various operations (e.g., receiving, obtaining, monitoring, outputting, transmitting) using or otherwise in cooperation with the receiver 410, the transmitter 415, or both. For example, the communications manager 420 may receive information from the receiver 410, send information to the transmitter 415, or be integrated in combination with the receiver 410, the transmitter 415, or both to obtain information, output information, or perform various other operations as described herein.

The communications manager 420 may support wireless communication at a UE in accordance with examples as disclosed herein. For example, the communications manager 420 may be configured as or otherwise support a means for receiving, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The communications manager 420 may be configured as or otherwise support a means for receiving, while in a first operational state and based on the control signaling, an RF waveform within a WUS monitoring occasion of the set of multiple WUS monitoring occasions. The communications manager 420 may be configured as or otherwise support a means for determining whether the received RF waveform is associated with the first binary sequence. The communications manager 420 may be configured as or otherwise support a means for transitioning from the first operational state to a second operational state based on determining that the received RF waveform is associated with the first binary sequence, where the second operational state is associated with a higher power consumption compared to the first operational state.

By including or configuring the communications manager 420 in accordance with examples as described herein, the device 405 (e.g., a processor controlling or otherwise coupled with the receiver 410, the transmitter 415, the communications manager 420, or a combination thereof) may support techniques that enable the use of binary WUS sequences that reduce processing requirements and complexity at receiver devices. In particular, by generating a set of binary sequences that each exhibit a minimum distance threshold from one another, aspects of the present disclosure may enable receiver devices (e.g., UEs 115) to compare binary sequences associated with received RF waveforms to the one or more binary sequences assigned to the receiver device. In other words, techniques described herein may reduce or eliminate the need for receiver devices to compare binary sequences to every binary sequence within the universe of binary sequences used by the network. As such, techniques described herein may reduce power consumption associated with processing WUSs at receiver devices, and improve power-saving capabilities of receiver devices operating in lower-power states. Moreover, the binary WUS sequence configurations described herein may reduce false alarms and mis-detections for WUSs, further reducing power consumption at receiver devices, improving the efficiency and reliability of WUSs, and leading to a more efficient use of wireless resources.

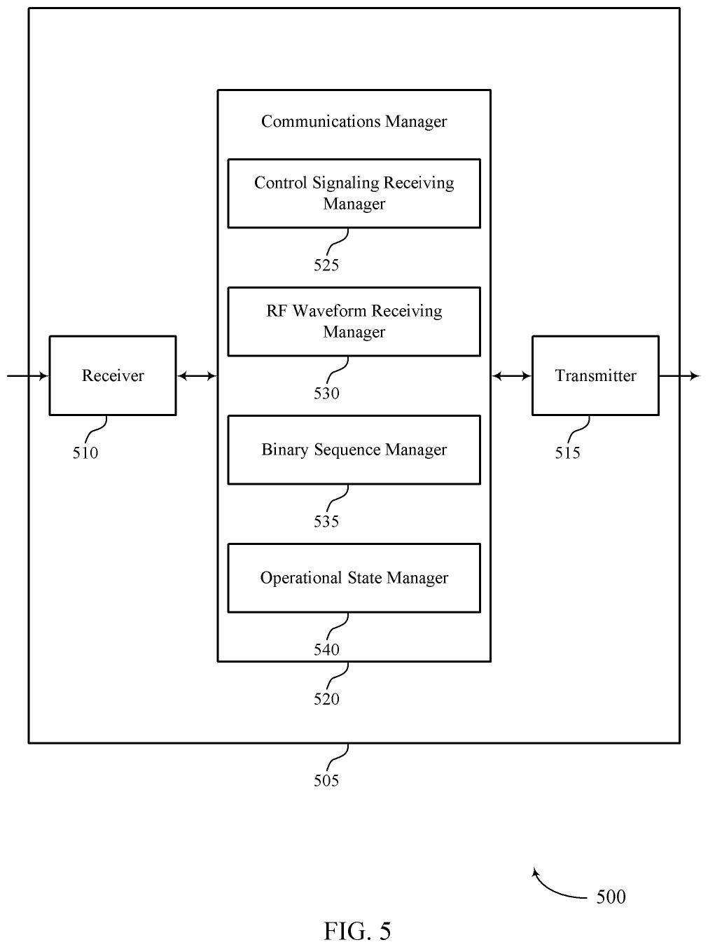

FIG. 5 shows a block diagram 500 of a device 505 that supports techniques for binary WUS sequences in accordance with one or more aspects of the present disclosure. The device 505 may be an example of aspects of a device 405 or a UE 115 as described herein. The device 505 may include a receiver 510, a transmitter 515, and a communications manager 520. The device 505 may also include a processor. Each of these components may be in communication with one another (e.g., via one or more buses).

The receiver 510 may provide a means for receiving information such as packets, user data, control information, or any combination thereof associated with various information channels (e.g., control channels, data channels, information channels related to techniques for binary WUS sequences). Information may be passed on to other components of the device 505. The receiver 510 may utilize a single antenna or a set of multiple antennas.

The transmitter 515 may provide a means for transmitting signals generated by other components of the device 505. For example, the transmitter 515 may transmit information such as packets, user data, control information, or any combination thereof associated with various information channels (e.g., control channels, data channels, information channels related to techniques for binary WUS sequences). In some examples, the transmitter 515 may be co-located with a receiver 510 in a transceiver module. The transmitter 515 may utilize a single antenna or a set of multiple antennas.

The device 505, or various components thereof, may be an example of means for performing various aspects of techniques for binary WUS sequences as described herein. For example, the communications manager 520 may include a control signaling receiving manager 525, an RF waveform receiving manager 530, a binary sequence manager 535, an operational state manager 540, or any combination thereof. The communications manager 520 may be an example of aspects of a communications manager 420 as described herein. In some examples, the communications manager 520, or various components thereof, may be configured to perform various operations (e.g., receiving, obtaining, monitoring, outputting, transmitting) using or otherwise in cooperation with the receiver 510, the transmitter 515, or both. For example, the communications manager 520 may receive information from the receiver 510, send information to the transmitter 515, or be integrated in combination with the receiver 510, the transmitter 515, or both to obtain information, output information, or perform various other operations as described herein.

The communications manager 520 may support wireless communication at a UE in accordance with examples as disclosed herein. The control signaling receiving manager 525 may be configured as or otherwise support a means for receiving, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The RF waveform receiving manager 530 may be configured as or otherwise support a means for receiving, while in a first operational state and based on the control signaling, an RF waveform within a WUS monitoring occasion of the set of multiple WUS monitoring occasions. The binary sequence manager 535 may be configured as or otherwise support a means for determining whether the received RF waveform is associated with the first binary sequence. The operational state manager 540 may be configured as or otherwise support a means for transitioning from the first operational state to a second operational state based on determining that the received RF waveform is associated with the first binary sequence, where the second operational state is associated with a higher power consumption compared to the first operational state.

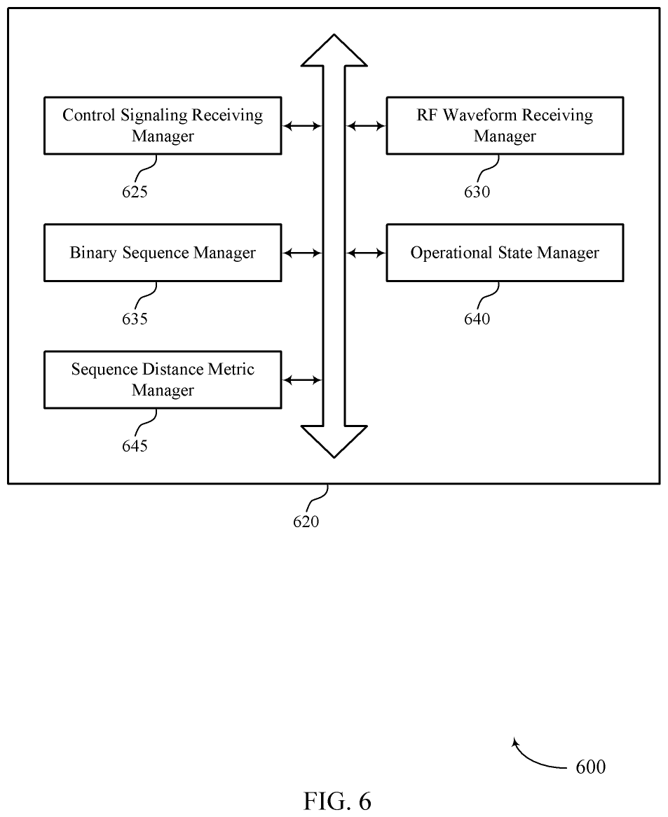

FIG. 6 shows a block diagram 600 of a communications manager 620 that supports techniques for binary WUS sequences in accordance with one or more aspects of the present disclosure. The communications manager 620 may be an example of aspects of a communications manager 420, a communications manager 520, or both, as described herein. The communications manager 620, or various components thereof, may be an example of means for performing various aspects of techniques for binary WUS sequences as described herein. For example, the communications manager 620 may include a control signaling receiving manager 625, an RF waveform receiving manager 630, a binary sequence manager 635, an operational state manager 640, a sequence distance metric manager 645, or any combination thereof. Each of these components may communicate, directly or indirectly, with one another (e.g., via one or more buses).

The communications manager 620 may support wireless communication at a UE in accordance with examples as disclosed herein. The control signaling receiving manager 625 may be configured as or otherwise support a means for receiving, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The RF waveform receiving manager 630 may be configured as or otherwise support a means for receiving, while in a first operational state and based on the control signaling, an RF waveform within a WUS monitoring occasion of the set of multiple WUS monitoring occasions. The binary sequence manager 635 may be configured as or otherwise support a means for determining whether the received RF waveform is associated with the first binary sequence. The operational state manager 640 may be configured as or otherwise support a means for transitioning from the first operational state to a second operational state based on determining that the received RF waveform is associated with the first binary sequence, where the second operational state is associated with a higher power consumption compared to the first operational state.

In some examples, the binary sequence manager 635 may be configured as or otherwise support a means for generating a second binary sequence associated with the received RF waveform. In some examples, the sequence distance metric manager 645 may be configured as or otherwise support a means for determining a sequence distance metric between the first binary sequence and the second binary sequence, where determining that the received RF waveform is associated with the first binary sequence is based on the sequence distance metric satisfying a second distance threshold that is less than the first distance threshold. In some examples, the sequence distance metric satisfies the second distance threshold based on the sequence distance metric being less than or equal to the second distance threshold.

In some examples, the control signaling receiving manager 625 may be configured as or otherwise support a means for receiving an indication of the second distance threshold via the control signaling. In some examples, the sequence distance metric manager 645 may be configured as or otherwise support a means for comparing the sequence distance metric to the second distance threshold based on the control signaling, where transitioning from the first operational state to the second operational state is based on the comparison.

In some examples, the RF waveform receiving manager 630 may be configured as or otherwise support a means for receiving, while in the first operational state and based on the control signaling, an additional RF waveform within an additional WUS monitoring occasion of the set of multiple WUS monitoring occasions. In some examples, the binary sequence manager 635 may be configured as or otherwise support a means for generating a second binary sequence associated with the additional RF waveform. In some examples, the operational state manager 640 may be configured as or otherwise support a means for remaining in the first operational state based on a sequence distance metric between the first binary sequence and the second binary sequence failing to satisfy a second distance threshold that is less than the first distance threshold.

In some examples, the first distance threshold is based on a length of the set of multiple binary sequences. In some examples, the first distance threshold is greater than or equal to half of the length of the set of multiple binary sequences. In some examples, the set of multiple sequence distance metrics between each respective pair of binary sequences satisfy the first distance threshold based on the set of multiple sequence distance metrics being greater than or equal to the first distance threshold. In some examples, the set of multiple binary sequences are generated based on a matrix generator of a binary linear block code.

In some examples, the binary linear block code includes a Golay code, a Reed Muller code, a Reed Solomon code, a Bose-Chaudhuri-Hocquenghem code, a Hamming code, a polar code, a LDPC code, or any combination thereof.

In some examples, the control signaling receiving manager 625 may be configured as or otherwise support a means for receiving, via the control signaling, additional control signaling, or both, a second binary sequence corresponding to a set of multiple UEs including the UE. In some examples, the binary sequence manager 635 may be configured as or otherwise support a means for determining whether the received RF waveform is associated with the second binary sequence, where transitioning from the first operational state to the second operational state is based on the RF waveform being associated with the first binary sequence, the second binary sequence, or both.

In some examples, the control signaling receiving manager 625 may be configured as or otherwise support a means for receiving, via the control signaling, a scrambling sequence associated with the first binary sequence, where determining whether the received RF waveform is associated with the first binary sequence is based on the scrambling sequence.

In some examples, the RF waveform receiving manager 630 may be configured as or otherwise support a means for generating a modified version of the received RF waveform based on the scrambling sequence. In some examples, the binary sequence manager 635 may be configured as or otherwise support a means for determining whether the modified version of the received RF waveform is associated with the first binary sequence, where transitioning from the first operational state to the second operational state is based on the modified version of the received RF waveform being associated with the first binary sequence.

In some examples, the RF waveform includes an OOK waveform, an FSK waveform, or both. In some examples, the set of multiple sequence distance metrics between each pair of binary sequences include Hamming distance property metrics.

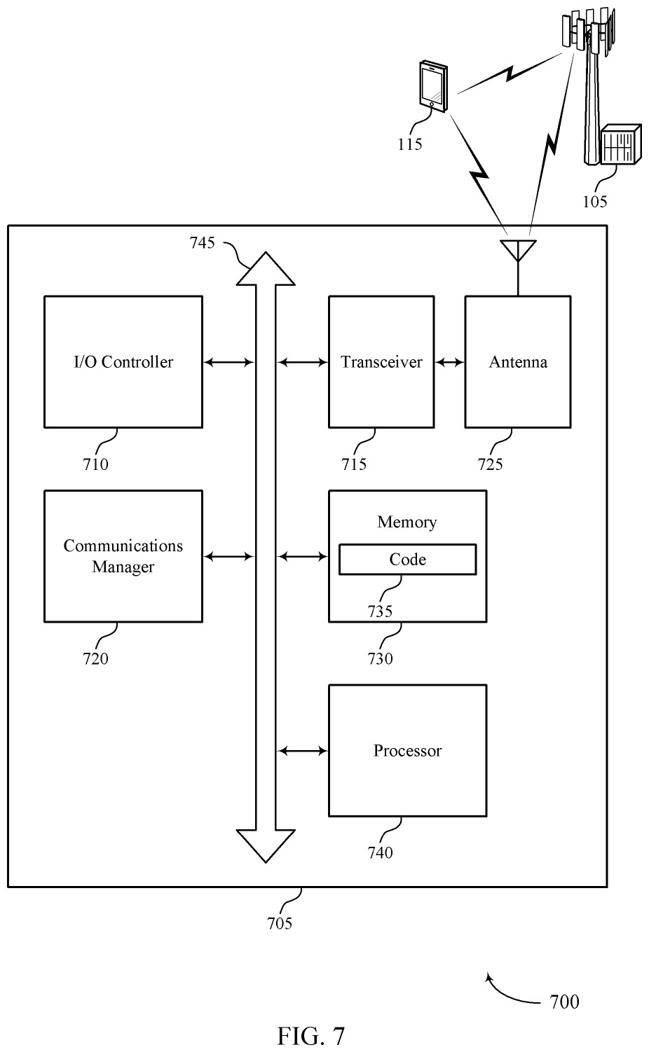

FIG. 7 shows a diagram of a system 700 including a device 705 that supports techniques for binary WUS sequences in accordance with one or more aspects of the present disclosure. The device 705 may be an example of or include the components of a device 405, a device 505, or a UE 115 as described herein. The device 705 may communicate (e.g., wirelessly) with one or more network entities 105, one or more UEs 115, or any combination thereof. The device 705 may include components for bi-directional voice and data communications including components for transmitting and receiving communications, such as a communications manager 720, an input/output (I/O) controller 710, a transceiver 715, an antenna 725, a memory 730, code 735, and a processor 740. These components may be in electronic communication or otherwise coupled (e.g., operatively, communicatively, functionally, electronically, electrically) via one or more buses (e.g., a bus 745).

The I/O controller 710 may manage input and output signals for the device 705. The I/O controller 710 may also manage peripherals not integrated into the device 705. In some cases, the I/O controller 710 may represent a physical connection or port to an external peripheral. In some cases, the I/O controller 710 may utilize an operating system such as iOS®, ANDROID®, MS-DOS®, MS-WINDOWS®, OS/2®, UNIX®, LINUX®, or another known operating system. Additionally or alternatively, the I/O controller 710 may represent or interact with a modem, a keyboard, a mouse, a touchscreen, or a similar device. In some cases, the I/O controller 710 may be implemented as part of a processor, such as the processor 740. In some cases, a user may interact with the device 705 via the I/O controller 710 or via hardware components controlled by the I/O controller 710.

In some cases, the device 705 may include a single antenna 725. However, in some other cases, the device 705 may have more than one antenna 725, which may be capable of concurrently transmitting or receiving multiple wireless transmissions. The transceiver 715 may communicate bi-directionally, via the one or more antennas 725, wired, or wireless links as described herein. For example, the transceiver 715 may represent a wireless transceiver and may communicate bi-directionally with another wireless transceiver. The transceiver 715 may also include a modem to modulate the packets, to provide the modulated packets to one or more antennas 725 for transmission, and to demodulate packets received from the one or more antennas 725. The transceiver 715, or the transceiver 715 and one or more antennas 725, may be an example of a transmitter 415, a transmitter 515, a receiver 410, a receiver 510, or any combination thereof or component thereof, as described herein.

The memory 730 may include random access memory (RAM) and read-only memory (ROM). The memory 730 may store computer-readable, computer-executable code 735 including instructions that, when executed by the processor 740, cause the device 705 to perform various functions described herein. The code 735 may be stored in a non-transitory computer-readable medium such as system memory or another type of memory. In some cases, the code 735 may not be directly executable by the processor 740 but may cause a computer (e.g., when compiled and executed) to perform functions described herein. In some cases, the memory 730 may contain, among other things, a basic I/O system (BIOS) which may control basic hardware or software operation such as the interaction with peripheral components or devices.

The processor 740 may include an intelligent hardware device (e.g., a general-purpose processor, a DSP, a CPU, a GPU, a microcontroller, an ASIC, an FPGA, a programmable logic device, a discrete gate or transistor logic component, a discrete hardware component, or any combination thereof). In some cases, the processor 740 may be configured to operate a memory array using a memory controller. In some other cases, a memory controller may be integrated into the processor 740. The processor 740 may be configured to execute computer-readable instructions stored in a memory (e.g., the memory 730) to cause the device 705 to perform various functions (e.g., functions or tasks supporting techniques for binary WUS sequences). For example, the device 705 or a component of the device 705 may include a processor 740 and memory 730 coupled with or to the processor 740, the processor 740 and memory 730 configured to perform various functions described herein.

The communications manager 720 may support wireless communication at a UE in accordance with examples as disclosed herein. For example, the communications manager 720 may be configured as or otherwise support a means for receiving, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The communications manager 720 may be configured as or otherwise support a means for receiving, while in a first operational state and based on the control signaling, an RF waveform within a WUS monitoring occasion of the set of multiple WUS monitoring occasions. The communications manager 720 may be configured as or otherwise support a means for determining whether the received RF waveform is associated with the first binary sequence. The communications manager 720 may be configured as or otherwise support a means for transitioning from the first operational state to a second operational state based on determining that the received RF waveform is associated with the first binary sequence, where the second operational state is associated with a higher power consumption compared to the first operational state.

By including or configuring the communications manager 720 in accordance with examples as described herein, the device 705 may support techniques that enable the use of binary WUS sequences that reduce processing requirements and complexity at receiver devices. In particular, by generating a set of binary sequences that each exhibit a minimum distance threshold from one another, aspects of the present disclosure may enable receiver devices (e.g., UEs 115) to compare binary sequences associated with received RF waveforms to the one or more binary sequences assigned to the receiver device. In other words, techniques described herein may reduce or eliminate the need for receiver devices to compare binary sequences to every binary sequence within the universe of binary sequences used by the network. As such, techniques described herein may reduce power consumption associated with processing WUSs at receiver devices, and improve power-saving capabilities of receiver devices operating in lower-power states. Moreover, the binary WUS sequence configurations described herein may reduce false alarms and mis-detections for WUSs, further reducing power consumption at receiver devices, improving the efficiency and reliability of WUSs, and leading to a more efficient use of wireless resources.

In some examples, the communications manager 720 may be configured to perform various operations (e.g., receiving, monitoring, transmitting) using or otherwise in cooperation with the transceiver 715, the one or more antennas 725, or any combination thereof. Although the communications manager 720 is illustrated as a separate component, in some examples, one or more functions described with reference to the communications manager 720 may be supported by or performed by the processor 740, the memory 730, the code 735, or any combination thereof. For example, the code 735 may include instructions executable by the processor 740 to cause the device 705 to perform various aspects of techniques for binary WUS sequences as described herein, or the processor 740 and the memory 730 may be otherwise configured to perform or support such operations.

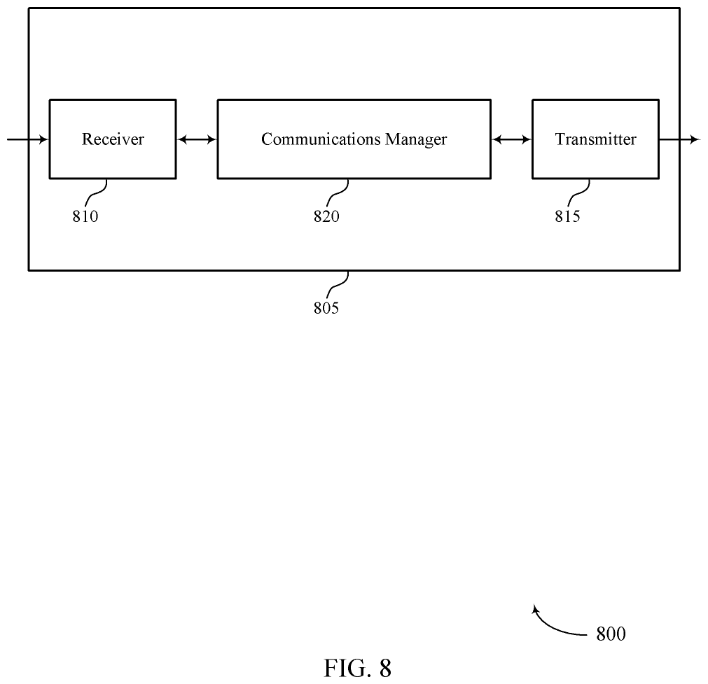

FIG. 8 shows a block diagram 800 of a device 805 that supports techniques for binary WUS sequences in accordance with one or more aspects of the present disclosure. The device 805 may be an example of aspects of a network entity 105 as described herein. The device 805 may include a receiver 810, a transmitter 815, and a communications manager 820. The device 805 may also include a processor. Each of these components may be in communication with one another (e.g., via one or more buses).

The receiver 810 may provide a means for obtaining (e.g., receiving, determining, identifying) information such as user data, control information, or any combination thereof (e.g., I/Q samples, symbols, packets, protocol data units, service data units) associated with various channels (e.g., control channels, data channels, information channels, channels associated with a protocol stack). Information may be passed on to other components of the device 805. In some examples, the receiver 810 may support obtaining information by receiving signals via one or more antennas. Additionally, or alternatively, the receiver 810 may support obtaining information by receiving signals via one or more wired (e.g., electrical, fiber optic) interfaces, wireless interfaces, or any combination thereof.

The transmitter 815 may provide a means for outputting (e.g., transmitting, providing, conveying, sending) information generated by other components of the device 805. For example, the transmitter 815 may output information such as user data, control information, or any combination thereof (e.g., I/Q samples, symbols, packets, protocol data units, service data units) associated with various channels (e.g., control channels, data channels, information channels, channels associated with a protocol stack). In some examples, the transmitter 815 may support outputting information by transmitting signals via one or more antennas. Additionally, or alternatively, the transmitter 815 may support outputting information by transmitting signals via one or more wired (e.g., electrical, fiber optic) interfaces, wireless interfaces, or any combination thereof. In some examples, the transmitter 815 and the receiver 810 may be co-located in a transceiver, which may include or be coupled with a modem.

The communications manager 820, the receiver 810, the transmitter 815, or various combinations thereof or various components thereof may be examples of means for performing various aspects of techniques for binary WUS sequences as described herein. For example, the communications manager 820, the receiver 810, the transmitter 815, or various combinations or components thereof may support a method for performing one or more of the functions described herein.

In some examples, the communications manager 820, the receiver 810, the transmitter 815, or various combinations or components thereof may be implemented in hardware (e.g., in communications management circuitry). The hardware may include a processor, a DSP, a CPU, a GPU, an ASIC, an FPGA or other programmable logic device, a microcontroller, discrete gate or transistor logic, discrete hardware components, or any combination thereof configured as or otherwise supporting a means for performing the functions described in the present disclosure. In some examples, a processor and memory coupled with the processor may be configured to perform one or more of the functions described herein (e.g., by executing, by the processor, instructions stored in the memory).

Additionally, or alternatively, in some examples, the communications manager 820, the receiver 810, the transmitter 815, or various combinations or components thereof may be implemented in code (e.g., as communications management software) executed by a processor. If implemented in code executed by a processor, the functions of the communications manager 820, the receiver 810, the transmitter 815, or various combinations or components thereof may be performed by a general-purpose processor, a DSP, a CPU, a GPU, an ASIC, an FPGA, a microcontroller, or any combination of these or other programmable logic devices (e.g., configured as or otherwise supporting a means for performing the functions described in the present disclosure).

In some examples, the communications manager 820 may be configured to perform various operations (e.g., receiving, obtaining, monitoring, outputting, transmitting) using or otherwise in cooperation with the receiver 810, the transmitter 815, or both. For example, the communications manager 820 may receive information from the receiver 810, send information to the transmitter 815, or be integrated in combination with the receiver 810, the transmitter 815, or both to obtain information, output information, or perform various other operations as described herein.

The communications manager 820 may support wireless communication at a network entity in accordance with examples as disclosed herein. For example, the communications manager 820 may be configured as or otherwise support a means for transmitting, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The communications manager 820 may be configured as or otherwise support a means for transmitting, to the UE within a WUS monitoring occasion of the set of multiple WUS monitoring occasions and while the UE is in a first operational state, an RF waveform corresponding to the first binary sequence, where the RF waveform is transmitted based on the control signaling. The communications manager 820 may be configured as or otherwise support a means for communicating message traffic to the UE based on transmitting the RF waveform.

By including or configuring the communications manager 820 in accordance with examples as described herein, the device 805 (e.g., a processor controlling or otherwise coupled with the receiver 810, the transmitter 815, the communications manager 820, or a combination thereof) may support techniques that enable the use of binary WUS sequences that reduce processing requirements and complexity at receiver devices. In particular, by generating a set of binary sequences that each exhibit a minimum distance threshold from one another, aspects of the present disclosure may enable receiver devices (e.g., UEs 115) to compare binary sequences associated with received RF waveforms to the one or more binary sequences assigned to the receiver device. In other words, techniques described herein may reduce or eliminate the need for receiver devices to compare binary sequences to every binary sequence within the universe of binary sequences used by the network. As such, techniques described herein may reduce power consumption associated with processing WUSs at receiver devices, and improve power-saving capabilities of receiver devices operating in lower-power states. Moreover, the binary WUS sequence configurations described herein may reduce false alarms and mis-detections for WUSs, further reducing power consumption at receiver devices, improving the efficiency and reliability of WUSs, and leading to a more efficient use of wireless resources.

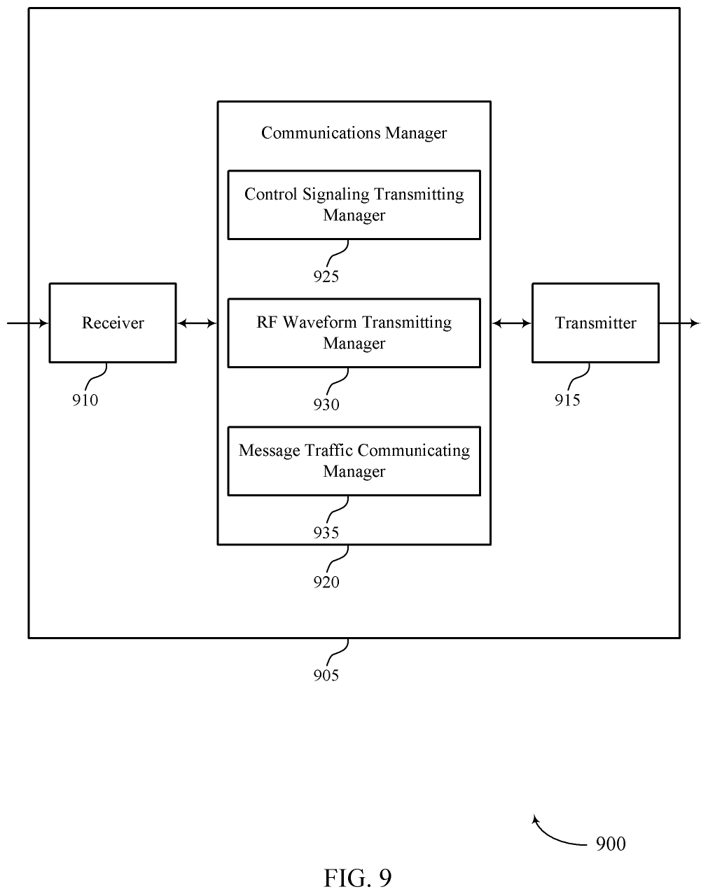

FIG. 9 shows a block diagram 900 of a device 905 that supports techniques for binary WUS sequences in accordance with one or more aspects of the present disclosure. The device 905 may be an example of aspects of a device 805 or a network entity 105 as described herein. The device 905 may include a receiver 910, a transmitter 915, and a communications manager 920. The device 905 may also include a processor. Each of these components may be in communication with one another (e.g., via one or more buses).

The receiver 910 may provide a means for obtaining (e.g., receiving, determining, identifying) information such as user data, control information, or any combination thereof (e.g., I/Q samples, symbols, packets, protocol data units, service data units) associated with various channels (e.g., control channels, data channels, information channels, channels associated with a protocol stack). Information may be passed on to other components of the device 905. In some examples, the receiver 910 may support obtaining information by receiving signals via one or more antennas. Additionally, or alternatively, the receiver 910 may support obtaining information by receiving signals via one or more wired (e.g., electrical, fiber optic) interfaces, wireless interfaces, or any combination thereof.

The transmitter 915 may provide a means for outputting (e.g., transmitting, providing, conveying, sending) information generated by other components of the device 905. For example, the transmitter 915 may output information such as user data, control information, or any combination thereof (e.g., I/Q samples, symbols, packets, protocol data units, service data units) associated with various channels (e.g., control channels, data channels, information channels, channels associated with a protocol stack). In some examples, the transmitter 915 may support outputting information by transmitting signals via one or more antennas. Additionally, or alternatively, the transmitter 915 may support outputting information by transmitting signals via one or more wired (e.g., electrical, fiber optic) interfaces, wireless interfaces, or any combination thereof. In some examples, the transmitter 915 and the receiver 910 may be co-located in a transceiver, which may include or be coupled with a modem.

The device 905, or various components thereof, may be an example of means for performing various aspects of techniques for binary WUS sequences as described herein. For example, the communications manager 920 may include a control signaling transmitting manager 925, an RF waveform transmitting manager 930, a message traffic communicating manager 935, or any combination thereof. The communications manager 920 may be an example of aspects of a communications manager 820 as described herein. In some examples, the communications manager 920, or various components thereof, may be configured to perform various operations (e.g., receiving, obtaining, monitoring, outputting, transmitting) using or otherwise in cooperation with the receiver 910, the transmitter 915, or both. For example, the communications manager 920 may receive information from the receiver 910, send information to the transmitter 915, or be integrated in combination with the receiver 910, the transmitter 915, or both to obtain information, output information, or perform various other operations as described herein.

The communications manager 920 may support wireless communication at a network entity in accordance with examples as disclosed herein. The control signaling transmitting manager 925 may be configured as or otherwise support a means for transmitting, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The RF waveform transmitting manager 930 may be configured as or otherwise support a means for transmitting, to the UE within a WUS monitoring occasion of the set of multiple WUS monitoring occasions and while the UE is in a first operational state, an RF waveform corresponding to the first binary sequence, where the RF waveform is transmitted based on the control signaling. The message traffic communicating manager 935 may be configured as or otherwise support a means for communicating message traffic to the UE based on transmitting the RF waveform.

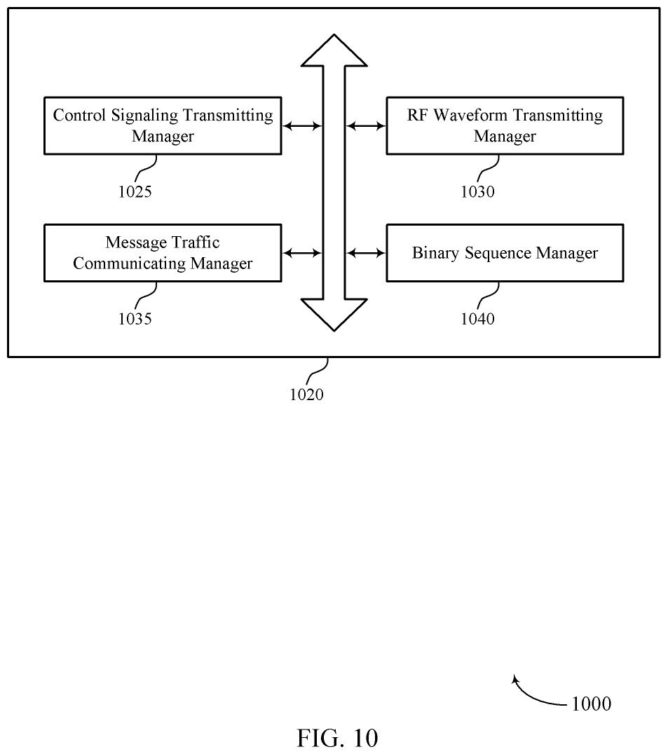

FIG. 10 shows a block diagram 1000 of a communications manager 1020 that supports techniques for binary WUS sequences in accordance with one or more aspects of the present disclosure. The communications manager 1020 may be an example of aspects of a communications manager 820, a communications manager 920, or both, as described herein. The communications manager 1020, or various components thereof, may be an example of means for performing various aspects of techniques for binary WUS sequences as described herein. For example, the communications manager 1020 may include a control signaling transmitting manager 1025, an RF waveform transmitting manager 1030, a message traffic communicating manager 1035, a binary sequence manager 1040, or any combination thereof. Each of these components may communicate, directly or indirectly, with one another (e.g., via one or more buses) which may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 1020 may support wireless communication at a network entity in accordance with examples as disclosed herein. The control signaling transmitting manager 1025 may be configured as or otherwise support a means for transmitting, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The RF waveform transmitting manager 1030 may be configured as or otherwise support a means for transmitting, to the UE within a WUS monitoring occasion of the set of multiple WUS monitoring occasions and while the UE is in a first operational state, an RF waveform corresponding to the first binary sequence, where the RF waveform is transmitted based on the control signaling. The message traffic communicating manager 1035 may be configured as or otherwise support a means for communicating message traffic to the UE based on transmitting the RF waveform.

In some examples, the message traffic communicating manager 1035 may be configured as or otherwise support a means for identifying the message traffic that is to be transmitted to the UE. In some examples, the binary sequence manager 1040 may be configured as or otherwise support a means for referencing a data object that maps the set of multiple binary sequences to a set of multiple RF waveforms and corresponding UEs based on identifying the message traffic, the set of multiple RF waveforms including the RF waveform. In some examples, the RF waveform transmitting manager 1030 may be configured as or otherwise support a means for identifying the RF waveform corresponding to the UE and the first binary sequence based on referencing the data object.

In some examples, the first distance threshold is based on a length of the set of multiple binary sequences. In some examples, the first distance threshold is greater than or equal to half of the length of the set of multiple binary sequences. In some examples, the set of multiple sequence distance metrics between each respective pair of binary sequences satisfy a distance threshold based on the set of multiple sequence distance metrics being greater than or equal to the distance threshold. In some examples, the set of multiple binary sequences are generated based on a matrix generator of a binary linear block code.

In some examples, the binary linear block code includes a Golay code, a Reed Muller code, a Reed Solomon code, a Bose-Chaudhuri-Hocquenghem code, a Hamming code, a polar code, a LDPC code, or any combination thereof.

In some examples, the control signaling transmitting manager 1025 may be configured as or otherwise support a means for transmitting, via the control signaling, additional control signaling, or both, a third binary sequence corresponding to a set of multiple UEs including the UE. In some examples, the RF waveform transmitting manager 1030 may be configured as or otherwise support a means for transmitting, to the set of multiple UEs within an additional WUS monitoring occasion of the set of multiple WUS monitoring occasions, an additional RF waveform corresponding to the third binary sequence. In some examples, the message traffic communicating manager 1035 may be configured as or otherwise support a means for communicating additional message traffic to the set of multiple UEs based on transmitting the additional RF waveform.

In some examples, the control signaling transmitting manager 1025 may be configured as or otherwise support a means for transmitting, via the control signaling, a scrambling sequence associated with the first binary sequence, where transmitting the RF waveform is based on the scrambling sequence. In some examples, the RF waveform transmitting manager 1030 may be configured as or otherwise support a means for generating the RF waveform based on the scrambling sequence.

In some examples, the control signaling transmitting manager 1025 may be configured as or otherwise support a means for transmitting an indication of a distance threshold associated with the set of multiple binary sequences via the control signaling, where transmitting the RF waveform, communicating the message traffic, or both, is based on the indication of the distance threshold.

In some examples, the RF waveform includes an OOK waveform, an FSK waveform, or both. In some examples, the set of multiple sequence distance metrics between each pair of binary sequences include Hamming distance property metrics.

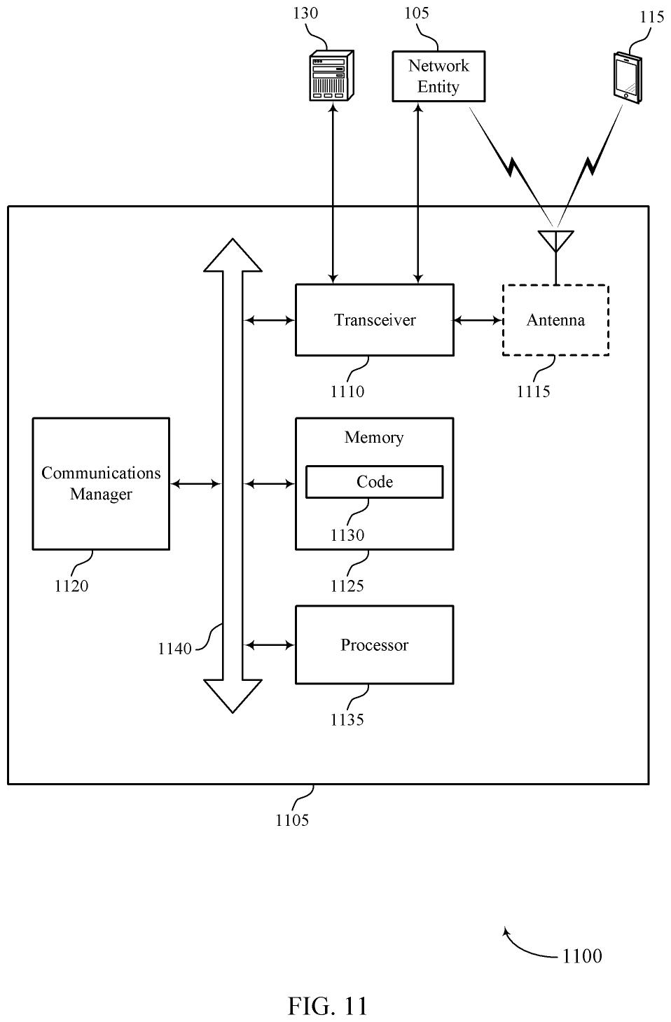

FIG. 11 shows a diagram of a system 1100 including a device 1105 that supports techniques for binary WUS sequences in accordance with one or more aspects of the present disclosure. The device 1105 may be an example of or include the components of a device 805, a device 905, or a network entity 105 as described herein. The device 1105 may communicate with one or more network entities 105, one or more UEs 115, or any combination thereof, which may include communications over one or more wired interfaces, over one or more wireless interfaces, or any combination thereof. The device 1105 may include components that support outputting and obtaining communications, such as a communications manager 1120, a transceiver 1110, an antenna 1115, a memory 1125, code 1130, and a processor 1135. These components may be in electronic communication or otherwise coupled (e.g., operatively, communicatively, functionally, electronically, electrically) via one or more buses (e.g., a bus 1140).

The transceiver 1110 may support bi-directional communications via wired links, wireless links, or both as described herein. In some examples, the transceiver 1110 may include a wired transceiver and may communicate bi-directionally with another wired transceiver. Additionally, or alternatively, in some examples, the transceiver 1110 may include a wireless transceiver and may communicate bi-directionally with another wireless transceiver. In some examples, the device 1105 may include one or more antennas 1115, which may be capable of transmitting or receiving wireless transmissions (e.g., concurrently). The transceiver 1110 may also include a modem to modulate signals, to provide the modulated signals for transmission (e.g., by one or more antennas 1115, by a wired transmitter), to receive modulated signals (e.g., from one or more antennas 1115, from a wired receiver), and to demodulate signals. In some implementations, the transceiver 1110 may include one or more interfaces, such as one or more interfaces coupled with the one or more antennas 1115 that are configured to support various receiving or obtaining operations, or one or more interfaces coupled with the one or more antennas 1115 that are configured to support various transmitting or outputting operations, or a combination thereof. In some implementations, the transceiver 1110 may include or be configured for coupling with one or more processors or memory components that are operable to perform or support operations based on received or obtained information or signals, or to generate information or other signals for transmission or other outputting, or any combination thereof. In some implementations, the transceiver 1110, or the transceiver 1110 and the one or more antennas 1115, or the transceiver 1110 and the one or more antennas 1115 and one or more processors or memory components (for example, the processor 1135, or the memory 1125, or both), may be included in a chip or chip assembly that is installed in the device 1105. In some examples, the transceiver may be operable to support communications via one or more communications links (e.g., a communication link 125, a backhaul communication link 120, a midhaul communication link 162, a fronthaul communication link 168).

The memory 1125 may include RAM and ROM. The memory 1125 may store computer-readable, computer-executable code 1130 including instructions that, when executed by the processor 1135, cause the device 1105 to perform various functions described herein. The code 1130 may be stored in a non-transitory computer-readable medium such as system memory or another type of memory. In some cases, the code 1130 may not be directly executable by the processor 1135 but may cause a computer (e.g., when compiled and executed) to perform functions described herein. In some cases, the memory 1125 may contain, among other things, a BIOS which may control basic hardware or software operation such as the interaction with peripheral components or devices.

The processor 1135 may include an intelligent hardware device (e.g., a general-purpose processor, a DSP, an ASIC, a CPU, a GPU, an FPGA, a microcontroller, a programmable logic device, discrete gate or transistor logic, a discrete hardware component, or any combination thereof). In some cases, the processor 1135 may be configured to operate a memory array using a memory controller. In some other cases, a memory controller may be integrated into the processor 1135. The processor 1135 may be configured to execute computer-readable instructions stored in a memory (e.g., the memory 1125) to cause the device 1105 to perform various functions (e.g., functions or tasks supporting techniques for binary WUS sequences). For example, the device 1105 or a component of the device 1105 may include a processor 1135 and memory 1125 coupled with the processor 1135, the processor 1135 and memory 1125 configured to perform various functions described herein. The processor 1135 may be an example of a cloud-computing platform (e.g., one or more physical nodes and supporting software such as operating systems, virtual machines, or container instances) that may host the functions (e.g., by executing code 1130) to perform the functions of the device 1105. The processor 1135 may be any one or more suitable processors capable of executing scripts or instructions of one or more software programs stored in the device 1105 (such as within the memory 1125). In some implementations, the processor 1135 may be a component of a processing system. A processing system may generally refer to a system or series of machines or components that receives inputs and processes the inputs to produce a set of outputs (which may be passed to other systems or components of, for example, the device 1105). For example, a processing system of the device 1105 may refer to a system including the various other components or subcomponents of the device 1105, such as the processor 1135, or the transceiver 1110, or the communications manager 1120, or other components or combinations of components of the device 1105. The processing system of the device 1105 may interface with other components of the device 1105, and may process information received from other components (such as inputs or signals) or output information to other components. For example, a chip or modem of the device 1105 may include a processing system and one or more interfaces to output information, or to obtain information, or both. The one or more interfaces may be implemented as or otherwise include a first interface configured to output information and a second interface configured to obtain information, or a same interface configured to output information and to obtain information, among other implementations. In some implementations, the one or more interfaces may refer to an interface between the processing system of the chip or modem and a transmitter, such that the device 1105 may transmit information output from the chip or modem. Additionally, or alternatively, in some implementations, the one or more interfaces may refer to an interface between the processing system of the chip or modem and a receiver, such that the device 1105 may obtain information or signal inputs, and the information may be passed to the processing system. A person having ordinary skill in the art will readily recognize that a first interface also may obtain information or signal inputs, and a second interface also may output information or signal outputs.

In some examples, a bus 1140 may support communications of (e.g., within) a protocol layer of a protocol stack. In some examples, a bus 1140 may support communications associated with a logical channel of a protocol stack (e.g., between protocol layers of a protocol stack), which may include communications performed within a component of the device 1105, or between different components of the device 1105 that may be co-located or located in different locations (e.g., where the device 1105 may refer to a system in which one or more of the communications manager 1120, the transceiver 1110, the memory 1125, the code 1130, and the processor 1135 may be located in one of the different components or divided between different components).

In some examples, the communications manager 1120 may manage aspects of communications with a core network 130 (e.g., via one or more wired or wireless backhaul links). For example, the communications manager 1120 may manage the transfer of data communications for client devices, such as one or more UEs 115. In some examples, the communications manager 1120 may manage communications with other network entities 105, and may include a controller or scheduler for controlling communications with UEs 115 in cooperation with other network entities 105. In some examples, the communications manager 1120 may support an X2 interface within an LTE/LTE-A wireless communications network technology to provide communication between network entities 105.

The communications manager 1120 may support wireless communication at a network entity in accordance with examples as disclosed herein. For example, the communications manager 1120 may be configured as or otherwise support a means for transmitting, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The communications manager 1120 may be configured as or otherwise support a means for transmitting, to the UE within a WUS monitoring occasion of the set of multiple WUS monitoring occasions and while the UE is in a first operational state, an RF waveform corresponding to the first binary sequence, where the RF waveform is transmitted based on the control signaling. The communications manager 1120 may be configured as or otherwise support a means for communicating message traffic to the UE based on transmitting the RF waveform.

By including or configuring the communications manager 1120 in accordance with examples as described herein, the device 1105 may support techniques that enable the use of binary WUS sequences that reduce processing requirements and complexity at receiver devices. In particular, by generating a set of binary sequences that each exhibit a minimum distance threshold from one another, aspects of the present disclosure may enable receiver devices (e.g., UEs 115) to compare binary sequences associated with received RF waveforms to the one or more binary sequences assigned to the receiver device. In other words, techniques described herein may reduce or eliminate the need for receiver devices to compare binary sequences to every binary sequence within the universe of binary sequences used by the network. As such, techniques described herein may reduce power consumption associated with processing WUSs at receiver devices, and improve power-saving capabilities of receiver devices operating in lower-power states. Moreover, the binary WUS sequence configurations described herein may reduce false alarms and mis-detections for WUSs, further reducing power consumption at receiver devices, improving the efficiency and reliability of WUSs, and leading to a more efficient use of wireless resources.

In some examples, the communications manager 1120 may be configured to perform various operations (e.g., receiving, obtaining, monitoring, outputting, transmitting) using or otherwise in cooperation with the transceiver 1110, the one or more antennas 1115 (e.g., where applicable), or any combination thereof. Although the communications manager 1120 is illustrated as a separate component, in some examples, one or more functions described with reference to the communications manager 1120 may be supported by or performed by the transceiver 1110, the processor 1135, the memory 1125, the code 1130, or any combination thereof. For example, the code 1130 may include instructions executable by the processor 1135 to cause the device 1105 to perform various aspects of techniques for binary WUS sequences as described herein, or the processor 1135 and the memory 1125 may be otherwise configured to perform or support such operations.

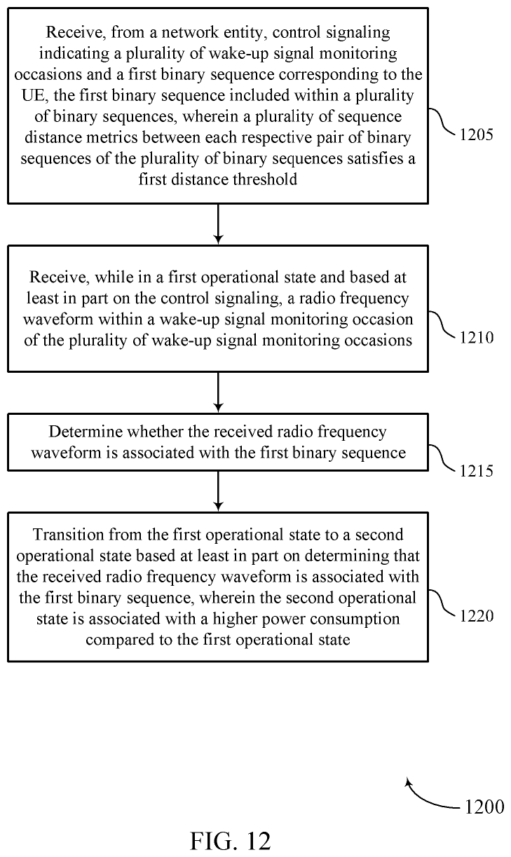

FIG. 12 shows a flowchart illustrating a method 1200 that supports techniques for binary WUS sequences in accordance with one or more aspects of the present disclosure. The operations of the method 1200 may be implemented by a UE or its components as described herein. For example, the operations of the method 1200 may be performed by a UE 115 as described with reference to FIGS. 1 through 7. In some examples, a UE may execute a set of instructions to control the functional elements of the UE to perform the described functions. Additionally, or alternatively, the UE may perform aspects of the described functions using special-purpose hardware.

At 1205, the method may include receiving, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The operations of 1205 may be performed in accordance with examples as disclosed herein. In some examples, aspects of the operations of 1205 may be performed by a control signaling receiving manager 625 as described with reference to FIG. 6.

At 1210, the method may include receiving, while in a first operational state and based at least in part on the control signaling, an RF waveform within a WUS monitoring occasion of the set of multiple WUS monitoring occasions. The operations of 1210 may be performed in accordance with examples as disclosed herein. In some examples, aspects of the operations of 1210 may be performed by an RF waveform receiving manager 630 as described with reference to FIG. 6.

At 1215, the method may include determining whether the received RF waveform is associated with the first binary sequence. The operations of 1215 may be performed in accordance with examples as disclosed herein. In some examples, aspects of the operations of 1215 may be performed by a binary sequence manager 635 as described with reference to FIG. 6.

At 1220, the method may include transitioning from the first operational state to a second operational state based at least in part on determining that the received RF waveform is associated with the first binary sequence, where the second operational state is associated with a higher power consumption compared to the first operational state. The operations of 1220 may be performed in accordance with examples as disclosed herein. In some examples, aspects of the operations of 1220 may be performed by an operational state manager 640 as described with reference to FIG. 6.

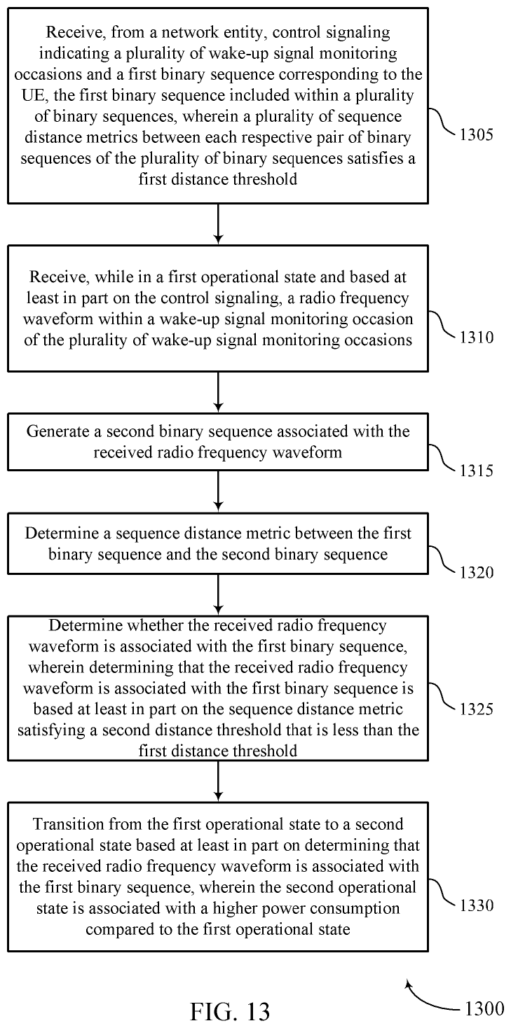

FIG. 13 shows a flowchart illustrating a method 1300 that supports techniques for binary WUS sequences in accordance with one or more aspects of the present disclosure. The operations of the method 1300 may be implemented by a UE or its components as described herein. For example, the operations of the method 1300 may be performed by a UE 115 as described with reference to FIGS. 1 through 7. In some examples, a UE may execute a set of instructions to control the functional elements of the UE to perform the described functions. Additionally, or alternatively, the UE may perform aspects of the described functions using special-purpose hardware.

At 1305, the method may include receiving, from a network entity, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The operations of 1305 may be performed in accordance with examples as disclosed herein. In some examples, aspects of the operations of 1305 may be performed by a control signaling receiving manager 625 as described with reference to FIG. 6.

At 1310, the method may include receiving, while in a first operational state and based at least in part on the control signaling, an RF waveform within a WUS monitoring occasion of the set of multiple WUS monitoring occasions. The operations of 1310 may be performed in accordance with examples as disclosed herein. In some examples, aspects of the operations of 1310 may be performed by an RF waveform receiving manager 630 as described with reference to FIG. 6.

At 1315, the method may include generating a second binary sequence associated with the received RF waveform. The operations of 1315 may be performed in accordance with examples as disclosed herein. In some examples, aspects of the operations of 1315 may be performed by a binary sequence manager 635 as described with reference to FIG. 6.

At 1320, the method may include determining a sequence distance metric between the first binary sequence and the second binary sequence. The operations of 1320 may be performed in accordance with examples as disclosed herein. In some examples, aspects of the operations of 1320 may be performed by a sequence distance metric manager 645 as described with reference to FIG. 6.

At 1325, the method may include determining whether the received RF waveform is associated with the first binary sequence, where determining that the received RF waveform is associated with the first binary sequence is based at least in part on the sequence distance metric satisfying a second distance threshold that is less than the first distance threshold. The operations of 1325 may be performed in accordance with examples as disclosed herein. In some examples, aspects of the operations of 1325 may be performed by a binary sequence manager 635 as described with reference to FIG. 6.

At 1330, the method may include transitioning from the first operational state to a second operational state based at least in part on determining that the received RF waveform is associated with the first binary sequence, where the second operational state is associated with a higher power consumption compared to the first operational state. The operations of 1330 may be performed in accordance with examples as disclosed herein. In some examples, aspects of the operations of 1330 may be performed by an operational state manager 640 as described with reference to FIG. 6.

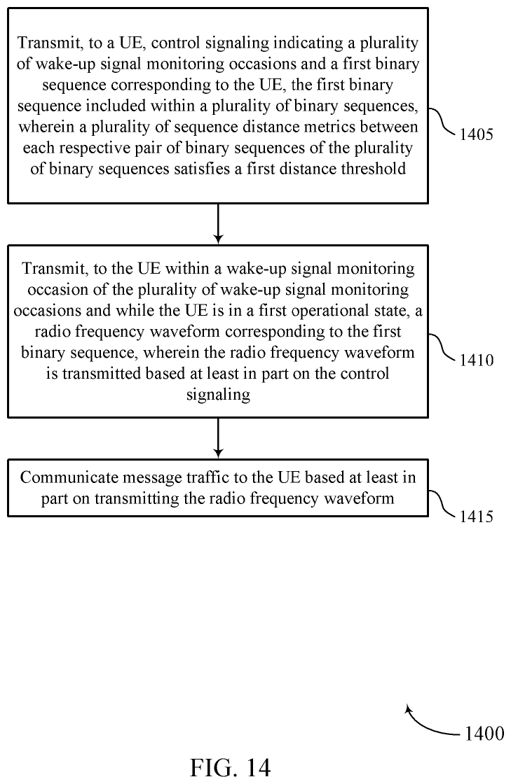

FIG. 14 shows a flowchart illustrating a method 1400 that supports techniques for binary WUS sequences in accordance with one or more aspects of the present disclosure. The operations of the method 1400 may be implemented by a network entity or its components as described herein. For example, the operations of the method 1400 may be performed by a network entity as described with reference to FIGS. 1 through 3 and 8 through 11. In some examples, a network entity may execute a set of instructions to control the functional elements of the network entity to perform the described functions. Additionally, or alternatively, the network entity may perform aspects of the described functions using special-purpose hardware.

At 1405, the method may include transmitting, to a UE, control signaling indicating a set of multiple WUS monitoring occasions and a first binary sequence corresponding to the UE, the first binary sequence included within a set of multiple binary sequences, where a set of multiple sequence distance metrics between each respective pair of binary sequences of the set of multiple binary sequences satisfies a first distance threshold. The operations of 1405 may be performed in accordance with examples as disclosed herein. In some examples, aspects of the operations of 1405 may be performed by a control signaling transmitting manager 1025 as described with reference to FIG. 10.

At 1410, the method may include transmitting, to the UE within a WUS monitoring occasion of the set of multiple WUS monitoring occasions and while the UE is in a first operational state, an RF waveform corresponding to the first binary sequence, where the RF waveform is transmitted based at least in part on the control signaling. The operations of 1410 may be performed in accordance with examples as disclosed herein. In some examples, aspects of the operations of 1410 may be performed by an RF waveform transmitting manager 1030 as described with reference to FIG. 10.

At 1415, the method may include communicating message traffic to the UE based at least in part on transmitting the RF waveform. The operations of 1415 may be performed in accordance with examples as disclosed herein. In some examples, aspects of the operations of 1415 may be performed by a message traffic communicating manager 1035 as described with reference to FIG. 10.

The following provides an overview of aspects of the present disclosure:

Aspect 1: A method for wireless communication at a UE, comprising: receiving, from a network entity, control signaling indicating a plurality of WUS monitoring occasions and a first binary sequence corresponding to the UE, the first binary sequence included within a plurality of binary sequences, wherein a plurality of sequence distance metrics between each respective pair of binary sequences of the plurality of binary sequences satisfies a first distance threshold; receiving, while in a first operational state and based at least in part on the control signaling, an RF waveform within a WUS monitoring occasion of the plurality of WUS monitoring occasions; determining whether the received RF waveform is associated with the first binary sequence; and transitioning from the first operational state to a second operational state based at least in part on determining that the received RF waveform is associated with the first binary sequence, wherein the second operational state is associated with a higher power consumption compared to the first operational state.

Aspect 2: The method of aspect 1, further comprising: generating a second binary sequence associated with the received RF waveform; and determining a sequence distance metric between the first binary sequence and the second binary sequence, wherein determining that the received RF waveform is associated with the first binary sequence is based at least in part on the sequence distance metric satisfying a second distance threshold that is less than the first distance threshold.

Aspect 3: The method of aspect 2, wherein the sequence distance metric satisfies the second distance threshold based on the sequence distance metric being less than or equal to the second distance threshold.

Aspect 4: The method of any of aspects 2 through 3, further comprising: receiving an indication of the second distance threshold via the control signaling; and comparing the sequence distance metric to the second distance threshold based at least in part on the control signaling, wherein transitioning from the first operational state to the second operational state is based at least in part on the comparison.

Aspect 5: The method of any of aspects 1 through 4, further comprising: receiving, while in the first operational state and based at least in part on the control signaling, an additional RF waveform within an additional WUS monitoring occasion of the plurality of WUS monitoring occasions; generating a second binary sequence associated with the additional RF waveform; and remaining in the first operational state based at least in part on a sequence distance metric between the first binary sequence and the second binary sequence failing to satisfy a second distance threshold that is less than the first distance threshold.

Aspect 6: The method of any of aspects 1 through 5, wherein the first distance threshold is based at least in part on a length of the plurality of binary sequences.

Aspect 7: The method of aspect 6, wherein the first distance threshold is greater than or equal to half of the length of the plurality of binary sequences.

Aspect 8: The method of any of aspects 1 through 7, wherein the plurality of sequence distance metrics between each respective pair of binary sequences satisfy the first distance threshold based on the plurality of sequence distance metrics being greater than or equal to the first distance threshold.

Aspect 9: The method of any of aspects 1 through 8, wherein the plurality of binary sequences are generated based at least in part on a matrix generator of a binary linear block code.

Aspect 10: The method of aspect 9, wherein the binary linear block code comprises a Golay code, a Reed Muller code, a Reed Solomon code, a Bose-Chaudhuri-Hocquenghem code, a Hamming code, a polar code, an LDPC code, or any combination thereof.

Aspect 11: The method of any of aspects 1 through 10, further comprising: receiving, via the control signaling, additional control signaling, or both, a second binary sequence corresponding to a plurality of UEs including the UE; and determining whether the received RF waveform is associated with the second binary sequence, wherein transitioning from the first operational state to the second operational state is based at least in part on the RF waveform being associated with the first binary sequence, the second binary sequence, or both.

Aspect 12: The method of any of aspects 1 through 11, further comprising: receiving, via the control signaling, a scrambling sequence associated with the first binary sequence, wherein determining whether the received RF waveform is associated with the first binary sequence is based at least in part on the scrambling sequence.

Aspect 13: The method of aspect 12, further comprising: generating a modified version of the received RF waveform based at least in part on the scrambling sequence; and determining whether the modified version of the received RF waveform is associated with the first binary sequence, wherein transitioning from the first operational state to the second operational state is based at least in part on the modified version of the received RF waveform being associated with the first binary sequence.

Aspect 14: The method of any of aspects 1 through 13, wherein the RF waveform comprises an OOK waveform, a frequency-shift keying waveform, or both.

Aspect 15: The method of any of aspects 1 through 14, wherein the plurality of sequence distance metrics between each pair of binary sequences comprise Hamming distance property metrics.

Aspect 16: A method for wireless communication at a network entity, comprising: transmitting, to a UE, control signaling indicating a plurality of WUS monitoring occasions and a first binary sequence corresponding to the UE, the first binary sequence included within a plurality of binary sequences, wherein a plurality of sequence distance metrics between each respective pair of binary sequences of the plurality of binary sequences satisfies a first distance threshold; transmitting, to the UE within a WUS monitoring occasion of the plurality of WUS monitoring occasions and while the UE is in a first operational state, an RF waveform corresponding to the first binary sequence, wherein the RF waveform is transmitted based at least in part on the control signaling; and communicating message traffic to the UE based at least in part on transmitting the RF waveform.

Aspect 17: The method of aspect 16, further comprising: identifying the message traffic that is to be transmitted to the UE; referencing a data object that maps the plurality of binary sequences to a plurality of RF waveforms and corresponding UEs based at least in part on identifying the message traffic, the plurality of RF waveforms including the RF waveform; and identifying the RF waveform corresponding to the UE and the first binary sequence based at least in part on referencing the data object.

Aspect 18: The method of any of aspects 16 through 17, wherein the first distance threshold is based at least in part on a length of the plurality of binary sequences.

Aspect 19: The method of aspect 18, wherein the first distance threshold is greater than or equal to half of the length of the plurality of binary sequences.

Aspect 20: The method of any of aspects 16 through 19, wherein the plurality of sequence distance metrics between each respective pair of binary sequences satisfy a distance threshold based on the plurality of sequence distance metrics being greater than or equal to the distance threshold.

Aspect 21: The method of any of aspects 16 through 20, wherein the plurality of binary sequences are generated based at least in part on a matrix generator of a binary linear block code.

Aspect 22: The method of aspect 21, wherein the binary linear block code comprises a Golay code, a Reed Muller code, a Reed Solomon code, a Bose-Chaudhuri-Hocquenghem code, a Hamming code, a polar code, an LDPC code, or any combination thereof.

Aspect 23: The method of any of aspects 16 through 22, further comprising: transmitting, via the control signaling, additional control signaling, or both, a third binary sequence corresponding to a plurality of UEs including the UE; transmitting, to the plurality of UEs within an additional WUS monitoring occasion of the plurality of WUS monitoring occasions, an additional RF waveform corresponding to the third binary sequence; and communicating additional message traffic to the plurality of UEs based at least in part on transmitting the additional RF waveform.

Aspect 24: The method of any of aspects 16 through 23, further comprising: transmitting, via the control signaling, a scrambling sequence associated with the first binary sequence, wherein transmitting the RF waveform is based at least in part on the scrambling sequence.

Aspect 25: The method of aspect 24, further comprising: generating the RF waveform based at least in part on the scrambling sequence.

Aspect 26: The method of any of aspects 16 through 25, further comprising: transmitting an indication of a distance threshold associated with the plurality of binary sequences via the control signaling, wherein transmitting the RF waveform, communicating the message traffic, or both, is based at least in part on the indication of the distance threshold.

Aspect 27: The method of any of aspects 16 through 26, wherein the RF waveform comprises an OOK waveform, a frequency-shift keying waveform, or both.

Aspect 28: The method of any of aspects 16 through 27, wherein the plurality of sequence distance metrics between each pair of binary sequences comprise Hamming distance property metrics.

Aspect 29: An apparatus for wireless communication at a UE, comprising at least one processor, and memory coupled to the at least one processor, the memory storing instructions executable by the at least one processor to cause the UE to perform a method of any of aspects 1 through 15.

Aspect 30: An apparatus for wireless communication at a UE, comprising at least one means for performing a method of any of aspects 1 through 15.

Aspect 31: A non-transitory computer-readable medium storing code for wireless communication at a UE, the code comprising instructions executable by at least one processor to perform a method of any of aspects 1 through 15.

Aspect 32: An apparatus for wireless communication at a network entity, comprising at least one processor, and memory coupled to the at least one processor, the memory storing instructions executable by the at least one processor to cause the network entity to perform a method of any of aspects 16 through 28.

Aspect 33: An apparatus for wireless communication at a network entity, comprising at least one means for performing a method of any of aspects 16 through 28.

Aspect 34: A non-transitory computer-readable medium storing code for wireless communication at a network entity, the code comprising instructions executable by at least one processor to perform a method of any of aspects 16 through 28.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein. Components within a wireless communication system may be coupled (for example, operatively, communicatively, functionally, electronically, and/or electrically) to each other.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a GPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented using hardware, software executed by a processor, or any combination thereof. Software shall be construed broadly to mean instructions, instruction sets, code, code segments, program code, programs, subprograms, software modules, applications, software applications, software packages, routines, subroutines, objects, executables, threads of execution, procedures, or functions, whether referred to as software, firmware, middleware, microcode, hardware description language, or otherwise. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, phase change memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (e.g., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.” As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

The term “determine” or “determining” encompasses a variety of actions and, therefore, “determining” can include calculating, computing, processing, deriving, investigating, looking up (such as via looking up in a table, a database or another data structure), ascertaining and the like. Also, “determining” can include receiving (e.g., receiving information), accessing (e.g., accessing data stored in memory) and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus for wireless communication at a user equipment (UE), comprising:
at least one processor; and
memory coupled to the at least one processor, the memory storing instructions executable by the at least one processor to cause the UE to:
receive, from a network entity, control signaling indicating a plurality of wake-up signal monitoring occasions and a first binary sequence corresponding to the UE, the first binary sequence included within a plurality of binary sequences, wherein a plurality of sequence distance metrics between each respective pair of binary sequences of the plurality of binary sequences satisfies a first distance threshold;
receive, while in a first operational state and based at least in part on the control signaling, a radio frequency waveform within a wake-up signal monitoring occasion of the plurality of wake-up signal monitoring occasions;
determine whether the received radio frequency waveform is associated with the first binary sequence; and
transition from the first operational state to a second operational state based at least in part on determining that the received radio frequency waveform is associated with the first binary sequence, wherein the second operational state is associated with a higher power consumption compared to the first operational state.

2. The apparatus of claim 1, wherein the instructions are further executable by the at least one processor to cause the UE to:
generate a second binary sequence associated with the received radio frequency waveform; and
determine a sequence distance metric between the first binary sequence and the second binary sequence, wherein determining that the received radio frequency waveform is associated with the first binary sequence is based at least in part on the sequence distance metric satisfying a second distance threshold that is less than the first distance threshold.

3. The apparatus of claim 2, wherein the sequence distance metric satisfies the second distance threshold based on the sequence distance metric being less than or equal to the second distance threshold.

4. The apparatus of claim 2, wherein the instructions are further executable by the at least one processor to cause the UE to:
receive an indication of the second distance threshold via the control signaling; and
compare the sequence distance metric to the second distance threshold based at least in part on the control signaling, wherein transitioning from the first operational state to the second operational state is based at least in part on the comparison.

5. The apparatus of claim 1, wherein the instructions are further executable by the at least one processor to cause the UE to:
receive, while in the first operational state and based at least in part on the control signaling, an additional radio frequency waveform within an additional wake-up signal monitoring occasion of the plurality of wake-up signal monitoring occasions;
generate a second binary sequence associated with the additional radio frequency waveform; and
remain in the first operational state based at least in part on a sequence distance metric between the first binary sequence and the second binary sequence failing to satisfy a second distance threshold that is less than the first distance threshold.

6. The apparatus of claim 1, wherein the first distance threshold is based at least in part on a length of the plurality of binary sequences.

7. The apparatus of claim 6, wherein the first distance threshold is greater than or equal to half of the length of the plurality of binary sequences.

8. The apparatus of claim 1, wherein the plurality of sequence distance metrics between each respective pair of binary sequences satisfy the first distance threshold based on the plurality of sequence distance metrics being greater than or equal to the first distance threshold.

9. The apparatus of claim 1, wherein the plurality of binary sequences are generated based at least in part on a matrix generator of a binary linear block code.

10. The apparatus of claim 9, wherein the binary linear block code comprises a Golay code, a Reed Muller code, a Reed Solomon code, a Bose-Chaudhuri-Hocquenghem code, a Hamming code, a polar code, a low-density parity-check code, or any combination thereof.

11. The apparatus of claim 1, wherein the instructions are further executable by the at least one processor to cause the UE to:
receive, via the control signaling, additional control signaling, or both, a second binary sequence corresponding to a plurality of UEs including the UE; and
determine whether the received radio frequency waveform is associated with the second binary sequence, wherein transitioning from the first operational state to the second operational state is based at least in part on the radio frequency waveform being associated with the first binary sequence, the second binary sequence, or both.

12. The apparatus of claim 1, wherein the instructions are further executable by the at least one processor to cause the UE to:
receive, via the control signaling, a scrambling sequence associated with the first binary sequence, wherein determining whether the received radio frequency waveform is associated with the first binary sequence is based at least in part on the scrambling sequence.

13. The apparatus of claim 12, wherein the instructions are further executable by the at least one processor to cause the UE to:
generate a modified version of the received radio frequency waveform based at least in part on the scrambling sequence; and
determine whether the modified version of the received radio frequency waveform is associated with the first binary sequence, wherein transitioning from the first operational state to the second operational state is based at least in part on the modified version of the received radio frequency waveform being associated with the first binary sequence.

14. The apparatus of claim 1, wherein the radio frequency waveform comprises an on-off-keying waveform, a frequency-shift keying waveform, or both.

15. The apparatus of claim 1, wherein the plurality of sequence distance metrics between each pair of binary sequences comprise Hamming distance property metrics.

16. An apparatus for wireless communication at a network entity, comprising:
at least one processor; and
memory coupled to the at least one processor, the memory storing instructions executable by the at least one processor to cause the network entity to:
transmit, to a user equipment (UE), control signaling indicating a plurality of wake-up signal monitoring occasions and a first binary sequence corresponding to the UE, the first binary sequence included within a plurality of binary sequences, wherein a plurality of sequence distance metrics between each respective pair of binary sequences of the plurality of binary sequences satisfies a first distance threshold;
transmit, to the UE within a wake-up signal monitoring occasion of the plurality of wake-up signal monitoring occasions and while the UE is in a first operational state, a radio frequency waveform corresponding to the first binary sequence, wherein the radio frequency waveform is transmitted based at least in part on the control signaling; and
communicate message traffic to the UE based at least in part on transmitting the radio frequency waveform.

17. The apparatus of claim 16, wherein the instructions are further executable by the at least one processor to cause the network entity to:
identify the message traffic that is to be transmitted to the UE;
reference a data object that maps the plurality of binary sequences to a plurality of radio frequency waveforms and corresponding UEs based at least in part on identifying the message traffic, the plurality of radio frequency waveforms including the radio frequency waveform; and
identify the radio frequency waveform corresponding to the UE and the first binary sequence based at least in part on referencing the data object.

18. The apparatus of claim 16, wherein the first distance threshold is based at least in part on a length of the plurality of binary sequences.

19. The apparatus of claim 18, wherein the first distance threshold is greater than or equal to half of the length of the plurality of binary sequences.

20. The apparatus of claim 16, wherein the plurality of sequence distance metrics between each respective pair of binary sequences satisfy a distance threshold based on the plurality of sequence distance metrics being greater than or equal to the distance threshold.

21. The apparatus of claim 16, wherein the plurality of binary sequences are generated based at least in part on a matrix generator of a binary linear block code.

22. The apparatus of claim 21, wherein the binary linear block code comprises a Golay code, a Reed Muller code, a Reed Solomon code, a Bose-Chaudhuri-Hocquenghem code, a Hamming code, a polar code, a low-density parity-check code, or any combination thereof.

23. The apparatus of claim 16, wherein the instructions are further executable by the at least one processor to cause the network entity to:
transmit, via the control signaling, additional control signaling, or both, a third binary sequence corresponding to a plurality of UEs including the UE;
transmit, to the plurality of UEs within an additional wake-up signal monitoring occasion of the plurality of wake-up signal monitoring occasions, an additional radio frequency waveform corresponding to the third binary sequence; and
communicate additional message traffic to the plurality of UEs based at least in part on transmitting the additional radio frequency waveform.

24. The apparatus of claim 16, wherein the instructions are further executable by the at least one processor to cause the network entity to:
transmit, via the control signaling, a scrambling sequence associated with the first binary sequence, wherein transmitting the radio frequency waveform is based at least in part on the scrambling sequence.

25. The apparatus of claim 24, wherein the instructions are further executable by the at least one processor to cause the network entity to:
generate the radio frequency waveform based at least in part on the scrambling sequence.

26. The apparatus of claim 16, wherein the instructions are further executable by the at least one processor to cause the network entity to:
transmit an indication of a distance threshold associated with the plurality of binary sequences via the control signaling, wherein transmitting the radio frequency waveform, communicating the message traffic, or both, is based at least in part on the indication of the distance threshold.

27. The apparatus of claim 16, wherein the radio frequency waveform comprises an on-off-keying waveform, a frequency-shift keying waveform, or both.

28. The apparatus of claim 16, wherein the plurality of sequence distance metrics between each pair of binary sequences comprise Hamming distance property metrics.

29. A method for wireless communication at a user equipment (UE), comprising:
receiving, from a network entity, control signaling indicating a plurality of wake-up signal monitoring occasions and a first binary sequence corresponding to the UE, the first binary sequence included within a plurality of binary sequences, wherein a plurality of sequence distance metrics between each respective pair of binary sequences of the plurality of binary sequences satisfies a first distance threshold;
receiving, while in a first operational state and based at least in part on the control signaling, a radio frequency waveform within a wake-up signal monitoring occasion of the plurality of wake-up signal monitoring occasions;
determining whether the received radio frequency waveform is associated with the first binary sequence; and
transitioning from the first operational state to a second operational state based at least in part on determining that the received radio frequency waveform is associated with the first binary sequence, wherein the second operational state is associated with a higher power consumption compared to the first operational state.

30. A method for wireless communication at a network entity, comprising:
transmitting, to a user equipment (UE), control signaling indicating a plurality of wake-up signal monitoring occasions and a first binary sequence corresponding to the UE, the first binary sequence included within a plurality of binary sequences, wherein a plurality of sequence distance metrics between each respective pair of binary sequences of the plurality of binary sequences satisfies a first distance threshold;
transmitting, to the UE within a wake-up signal monitoring occasion of the plurality of wake-up signal monitoring occasions and while the UE is in a first operational state, a radio frequency waveform corresponding to the first binary sequence, wherein the radio frequency waveform is transmitted based at least in part on the control signaling; and
communicating message traffic to the UE based at least in part on transmitting the radio frequency waveform.
